(19) United States
(12) Patent Application Publication
(10) Pub. No.: US 2004/0097103 A1
(43) Pub. Date: May 20, 2004

(54) Laser annealing device and thin-film transistor manufacturing method

(76) Inventors: Yutaka Imai, Tokyo (JP); Nobuhiko Umezu, Kanagawa (JP); Akihiko Asano, Kanagawa (JP); Shin Hotta, Tokyo (JP); Koichi Tatsuki, Kanagawa (JP); Atsushi Fukumoto, Kanagawa (JP); Shigeo Kubota, Kanagawa (JP)

Correspondence Address: David R Metzger, Sonnenschein Nath & Rosenthal, Wacker Drive Station, P O Box #061080, Chicago, IL, 60606-1080, US

(21) Appl. No.: 10/466,096

(22) PCT Filed: Nov. 12, 2002
(86) PCT No.: PCT/JP02/11796

(30) Foreign Application Priority Data
Nov. 12, 2001 (JP) 2001-346454
Nov. 16, 2001 (JP) 2001-352162
Dec. 16, 2001 (JP) 2001-373189
Dec. 7, 2001 (JP) 2001-374921

(51) Int. Cl. H01L 21/00; H01L 21/324; H01L 21/26

(52) U.S. Cl. 438/795; 438/151; 438/166

(57) ABSTRACT

A laser annealing device (10) includes a laser oscillator (12), radiating a pulsed laser light beam of a preset period, and an illuminating optical system (15) for illuminating a pulsed laser light beam to an amorphous silicon film (1). The illuminating optical system (15) manages control for moving a laser spot so that a plural number of light pulses will be illuminated on the same location on the amorphous silicon film (1). The laser oscillator (12) radiates a laser light beam of a pulse generation period shorter than the reference period. The reference period is a time interval as from the radiation timing of illumination of a pulsed laser light beam on the surface of the film (1) until the timing of reversion of the substrate temperature raised due to the illumination of the laser light beam to the original substrate temperature.

### TECHNICAL FIELD

This invention relates to a method and an apparatus for laser annealing by illuminating the laser light on a substance, and to a method and an apparatus for the preparation of a thin-film transistor including a laser annealing process for effecting the laser annealing.

This application claims priority of Japanese Patent Application No.2001-346454, filed on Nov. 12, 2001, Japanese Patent Application No.2001-352162, filed on Nov. 16, 2001, Japanese Patent Application No.2001-374921, filed on Dec. 7, 2001, and Japanese Patent Application No.2001-373189, filed on Dec. 6, 2001, the entireties of which are incorporated by reference herein.

### BACKGROUND ART

(1) Such a technique has been developed in which a polysilicon film is formed on an insulating substrate, such as a glass substrate or a plastics substrate to fabricate a thin-film transistor (TFT) using this polysilicon film as a channel layer. Since the single-crystal silicon substrate is expensive, while the insulating substrate, such as glass substrate or plastics substrate, is inexpensive, a semiconductor device employing the insulating substrate is favorable insofar as the cost is concerned. Moreover, this semiconductor device can be increased in size. The TFT, generally used as a switching device for a liquid crystal display, has recently been proposed to be used for an advanced functional device, such as central processing unit (CPU).

The routine practice in forming a polysilicon film on the insulating substrate is forming an amorphous silicon film on the insulating substrate by for example vapor deposition, followed by laser annealing the so formed amorphous silicon film.

Meanwhile, the mobility of electrons or holes in the polysilicon film is said to be changed, depending on the crystal grain size or the state of the crystal boundary surface. Specifically, when the polysilicon film is of a large crystal grain size and of a homogeneous crystal grain size distribution, the carrier mobility is increased, such that a semiconductor device with a high operating speed and low power consumption may be produced.

Thus, for producing a TFT with high precision, such laser annealing is desired which is able to enlarge the crystal grain size and to homogenize the crystal grain size of the polysilicon film.

(2) The crystal grain size of the polysilicon film is felt to depend significantly on the rate of cooling in re-crystallization of silicon melted on heating with the laser light. Although the reason for this has not been clarified quantitatively, it is contemplated that, qualitatively, there is noticed a tendency that, the faster the rate of cooling following the melting on heating, the smaller becomes the crystal grain size, there occurring no crystal growth, and that, the slower the cooling rate, the coarser becomes the crystal grain, there occurring the crystal growth.

Thus, such laser annealing, in which it is possible to slow down the cooling rate at the time of silicon re-crystallization, is desired.

As a method for slowing down the cooling rate at the time of silicon re-crystallization, such a method has been proposed in which laser annealing is performed in a state the insulating substrate has been heated to a temperature not dissolving the insulating substrate. As a method for heating the insulating substrate, such a method of heating the insulating substrate with a heater or with a flash lamp has been proposed.

However, with the above-described heating method, a heating mechanism must be provided, thus complicating the structure of the laser annealing device. Moreover, the operation of heating the insulating substrate is time-consuming, thus lowering the throughput of the device. Additionally, the substrate position is moved due to thermal expansion of the insulating substrate, attendant on the heating, so that it becomes impossible to illuminate the laser light at a correct position.

Thus, with a conventional laser annealing device, it has not been possible to increase the crystal grain size or to homogenize the crystal grain size distribution by a simplified structure.

(3) In a conventional laser annealing device, a pulse oscillation type laser light source is generally used. However, if annealing with a laser light source, radiating e.g., the pulse laser light beam with a pulse width not longer than 10 nano-sec (nsec), is considered, the time which elapses since silicon is fused until the temperature reverts to the substrate temperature is shortened, thus speeding up the cooling. The result is that the time period during which the crystal growth takes place is shortened, with the result that the crystal grain size cannot be increased.

In general, for elongatingthe time period during which the crystal growth takes place, it is sufficient to protract the pulse light illuminating time, that is, to elongate the pulse width of the pulsed laser light beam. However, if the designing is made such as to maximize the laser light output power, it is extremely difficult to change the pulse width, given the characteristics of the laser light source.

As a method for protracting the time of illumination by one pulsed light beam without changing the pulse width, such a method has been proposed in which plural laser light beams radiated from respective different laser light sources are illuminated with temporal offset on the silicon film surface.

However, the excimer laser, used up to now for a laser annealing device, is unstable in its output, such that the pulse oscillation timing undergoes an error of not less than 100 nsec. It is therefore well-nigh impossible to reduce the pulse width of the laser light radiated from the plural excimer laser light sources to 10 nsec or less and to temporally offset the laser light beams radiated from the plural laser light sources to protract the illuminating time for one pulse radiation.

Thus, with the laser annealing device, employing the conventional excimer laser annealing device, it has not been possible to reduce the pulse width of the laser light source, to increase the crystal grain size of the polysilicon film and to homogenize the crystal grain size.

(4) The crystal grains of the polysilicon film are formed by generation of micro-sized crystal nuclei and by growth of the so generated crystal nuclei. That is, the crystal nuclei are generated in the initial stage of the re-crystallization.

It is contemplated that the crystal grain size of the polysilicon film differs in dependence upon whether the clustered state of crystal nuclei generated in the initial stage of re-crystallization is dense or thin.

For example, if the distance between the generated crystal nuclei is only small, the boundary surfaces of the neighboring crystals collide against one another in the course of the growth of the respective crystal nuclei to impede further growth. If conversely the distance between the generated crystal nuclei is not small, the boundary surfaces of the neighboring crystals do not collide against one another in the course of the growth of the respective crystal nuclei to permit the growth to a larger crystal grain size.

Thus, for increasing the crystal grain size of the polysilicon film and for homogenizing the crystal grain size distribution, it is sufficient to control the sites of generation of crystal nuclei to increase the distance between the neighboring crystal nuclei.

However, with the conventional laser annealing device, it is not possible to control the sites of generation of the crystal nuclei. Thus, with the conventional laser annealing device, it is not possible to increase the crystal grain size of the polysilicon film and to homogenize the crystal grain size distribution.

(5) Among different types of TFTs, there is a TFT of the type employing a bottom gate structure. In the following, the TFT of the type employing a bottom gate structure is termed a bottom gate type TFT. The bottom gate type TFT is such a TFT in which an electrode for a gate of, for example, molybdenum, is formed as a subjacent layer of the polysilicon film operating as a channel layer.

For producing a bottom gate type TFT, it is necessary to form a gate electrode on an insulating substrate, such as glass substrate, to form an amorphous silicon film thereon and to then apply laser annealing processing to the so formed amorphous silicon film.

When the laser annealing processing is applied to the amorphous silicon film of the bottom gate type TFT, there is raised a problem that the heat evolved on heating the silicon by laser illumination is dissipated via the subjacent gate electrode layer. As a consequence, there is produced energy differential between the portion of the silicon film not having the electrode for the gate as a subjacent layer and the portion thereof having the electrode for the gate as a subjacent layer, even though the laser light is illuminated with the constant energy, so that it becomes difficult to anneal the entire substrate with a uniform energy.

In particular, the laser light source of the conventional laser annealing device is the excimer laser. With the excimer laser, marked energy variations are noticed from one pulse to the next, such that it is extremely difficult to continue to supply the constant energy to the entire substrate. Consequently, with the polysilicon film, generated by the excimer laser annealing device, it is a frequent occurrence that the portion thereof having the gate electrode as a subjacent layer proves a defect due to insufficient laser light illumination or that the portion thereof not having the gate electrode as a subjacent layer proves a defect due to excessive laser light illumination, thus lowering the yield.

The result is that, in the conventional laser annealing device, it has been difficult, in producing the bottom gate type TFT, to enlarge the crystal grain size or to homogenize the crystal grain size distribution.

### DISCLOSURE OF THE INVENTION

It is therefore an object of the present invention to provide an apparatus and a method for laser annealing whereby it is possible to increase the crystal grain size of a polysilicon film and to homogenize the crystal grain size distribution thereof.

It is another object of the present invention to provide a method and an apparatus for producing a thin-film transistor whereby it is possible to form a polysilicon film with an increased crystal grain size and a homogenized crystal grain size distribution.

For accomplishing the above objects, the present invention provides a laser annealing apparatus, a laser annealing method and a thin-film transistor in which, in an annealing step of a polysil icon film, a laser light beam is radiated in a pulsed fashion at a period shorter than the reference period. The illuminated position of the laser light beam on the surface of a substance is moved so that the laser light beam radiated in a pulsed fashion from laser light beam radiating means will be illuminated a plural number of times on the same position on the surface of the substance. The reference period is a time interval as from the radiation timing of illumination of a pulsed laser light beam on the surface of the film until the timing of reversion of the substrate temperature, raised due to the illumination of the laser light beam, to the original substrate temperature.

For accomplishing the above objects, the present invention also provides a laser annealing apparatus and a laser annealing method, as well as thin-film transistor, in which, in an annealing step of a polysilicon film, a plural number of laser light beams are radiated in a pulsed fashion at a predetermined period, the plural laser light beams radiated are synthesized and illuminated on the surface of the substance, as control is managed for equating the period of pulse radiation of respective laser light beams and for shifting the timing of pulsed radiation of plural laser light beams to a timing such that, before light radiation of an optional laser light pulse comes to an end, the next laser light pulse is radiated.

For accomplishing the above objects, the present invention also provides a method and an apparatus for laser annealing in which a first laser light beam is generated, which first laser light beam has a predetermined portion with an energy different from that in the remaining portion having a homogenized energy distribution, a second laser light beam having a homogenized energy distribution is generated, the first and second laser light beams are synthesized together, the resulting synthesized laser light beam is illuminated on the surface of the substance, and the radiation timing of the first laser light beam and the radiation timing of the second laser light beam are controlled so that, after illumination of the first laser light beam on the surface of the substance, the second laser light beam is illuminated on the surface of the substance.

For accomplishing the above objects, the present invention provides a method and an apparatus for manufacturing a thin-film transistor in which a laser light beam of a wavelength not less than 250 nm and not larger than 550 nm, radiated from a solid laser light source, is illuminated on an amorphous silicon film formed on the substrate to form a polysilicon film of the bottom gate type thin-film transistor.

For accomplishing the above objects, the present invention provides a method and an apparatus for manufacturing a thin-film transistor in which an amorphous silicon film is formed on the substrate and the laser light is illuminated on the so formed amorphous film to form the polysilicon film of the bottom gate type thin-film transistor, as the film thickness of the amorphous silicon film is controlled, depending on the wavelength of the laser light beam, so that the transmittance of the laser light will be not less than 2% and not larger than 20%.

### BRIEF DESCRIPTION OF THE DRAWINGS

FIG. 1 is a block diagram showing the structure of a laser annealing device according to a first embodiment of the present invention.

FIG. 2 illustrates pulse driving signals output from a pulse signal generating unit provided in a laser annealing device according to a first embodiment of the present invention.

FIG. 3 illustrates the deflection of the laser light imparted to the laser light illuminated on a TFT substrate from an illuminating optical system provided to the laser annealing device according to the first embodiment of the present invention.

FIG. 4 illustrates a movement trajectory of a spot of the laser light illuminated from the illuminating optical system to the TFT substrate.

FIG. 5 illustrates the movement trajectory in case the shape of the spot of the illuminated laser light is linear.

FIG. 6 illustrates the relationship between the timing of the pulsed light and the movement trajectory of the light spot illuminated on the TFT substrate.

FIG. 7 is a graph showing changes in the temperature of the silicon film surface raised on illuminating one light pulse on an amorphous silicon film.

FIG. 8 is a graph showing changes in the temperature of the silicon film surface on illuminating the continuous pulsed light beam on an amorphous silicon film.

FIG. 9 is a block diagram showing the structure of a laser annealing device of the first embodiment having plural laser oscillators.

FIG. 10 is a block diagram showing the structure of a laser annealing device according to a second embodiment of the present invention.

FIG. 11 illustrates pulse driving signals output from a pulse signal generator provided to the laser annealing device according to the second embodiment of the present invention.

FIG. 12 illustrates the timing of synthesizing the pulsed light beams radiated from two laser oscillators.

FIGS. 13A to 13C illustrate temperature changes in the silicon film against time offset values of the two pulsed light beams.

FIG. 14 is a block diagram of a laser annealing device of the second embodiment provided with a large number of laser oscillators.

FIG. 15 is a block diagram of a laser annealing device of the second embodiment in case the pulsed light radiated from the laser oscillator is generated by injection seeding.

FIG. 16 is a block diagram showing the structure of a laser annealing device according to a third embodiment of the present invention.

FIGS. 17A and 17B illustrate the laser light which has passed through an optical system for crystal growth provided to the laser annealing device according to the third embodiment of the present invention.

FIGS. 18A and 18B illustrate the laser light which has passed through an optical system for nucleation provided to the laser annealing device according to the third embodiment of the present invention.

FIG. 19 illustrates the timing of generation of pulsed light shown in FIGS. 17A and 17B and that shown in FIGS. 18A and 18B.

FIG. 20 shows the state of crystallization of a polysilicon film in case of high density of crystal nuclei.

FIG. 21 shows the state of crystallization of a polysilicon film in case of low density of crystal nuclei.

FIG. 22 illustrates the generating timing of the pulsed light shown in FIGS. 17A and 17B and that shown in FIGS. 18A and 18B in case of synthesis of three or more pulsed light beams.

FIG. 23 is a block diagram of a laser annealing device in case only one laser oscillator is used.

FIG. 24 illustrates the schematic cross-sectional structure of a bottom gate type thin-film transistor.

FIG. 25 is a block diagram showing the structure of a laser annealing device according to a fourth embodiment of the present invention.

FIGS. 26A and 26B illustrate the shaping by the laser light employing a homogenizer.

FIG. 27 is a graph showing absorption coefficients of amorphous silicon and polysilicon for respective wavelengths.

FIG. 28 is a graph showing transmittance characteristics of the glass substrate for respective wavelengths of the illuminated laser light.

### BEST MODE FOR CARRYING OUT THE INVENTION

(First Embodiment)

As a first embodiment of the present invention, a laser annealing device performing the laser annealing, as the temperature of the insulating substrate has been raised, is now explained.

Meanwhile, the laser annealing device of the first embodiment is used in e.g., a polycrystallizing step in the manufacturing process for a thin film transistor (TFT) of forming a polysilicon film which is to become a channel layer. That is, the laser annealing device of the first embodiment is used in a step of illuminating the laser light on an amorphous silicon film formed on the glass substrate to effect annealing.

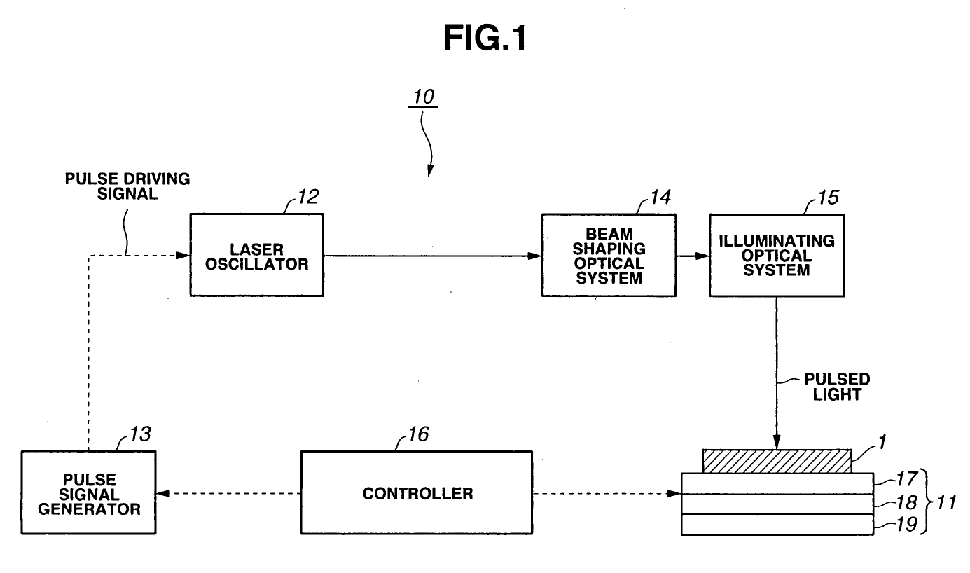

FIG. 1 shows the structure of a laser annealing device 10 of the first embodiment of the present invention. The laser annealing device 10 includes a movable stage 11, on which to set a TFT substrate 1 to be annealed, a laser oscillator 12 for radiating pulsed laser light, a pulse signal generator 13 for generating pulse driving signals of a predetermined period, a beam shaping optical system 14 for beam-shaping the laser light radiated from the laser oscillator 12, an illuminating optical system 15 for illuminating the beam-shaped laser light on the TFT substrate 1 set on the movable stage 11, and a controller 16.

The movable stage 11 is a table on which is set a flat plate shaped TFT substrate 1. The TFT substrate 1 means a unit comprised of a glass substrate as an insulating substrate and an amorphous silicon film formed thereon. The movable stage 11 has a highly planar setting surface for the TFT substrate 1. The movable stage 11 has a function of causing movement of the flat plate shaped TFT substrate 1 in a direction parallel to its major surface, and a function of causing movement of the flat plate shaped TFT substrate 1 in a direction perpendicular to its major surface.

Specifically, the movable stage 11 includes an X-stage 17, a Y-stage 18 and a Z-stage 19. The X-stage 17 and the Y-stage 18 cause movement of the flat plate shaped TFT substrate 1 in a direction parallel to its major surface. The X-stage 17 is a stage for causing movement thereon of the TFT substrate 1 in one direction (X-direction) parallel to the major surface of the TFT substrate 1. The Y-stage 18 is a stage for causing movement thereon of the TFT substrate 1 in a direction parallel to the major surface of the TFT substrate 1 and perpendicular to the X-direction (Y-direction). Thus, the X-stage 17 and the Y-stage 18 are able to shift the spot of the illuminated laser light to an arbitrary position on the TFT substrate 1. Consequently, the X-stage 17 and the Y-stage 18 are able to shift the TFT substrate 1 to a location where the laser annealing processing is to be performed. The Z-stage 19 causes movement of the flat plate shaped TFT substrate 1 in a direction perpendicular to its major surface. Thus, the Z-stage 19 is able to focus the focal position of the illuminated laser light correctly on the amorphous silicon film of the TFT substrate 1.

The movable stage 11 may include the function of securing the TFT substrate 1 thereto, while the movable stage 11 may include the function of adsorbing the TFT substrate 1 from its back side to affix the TFT substrate 1 to the movable stage 11.

The laser oscillator 12 radiates pulsed laser light for laser annealing the amorphous silicon film. Specifically, the laser oscillator 12 radiates pulsed laser light which repeats the sequence of alternate illumination and cessation of illumination every predetermined time interval. It is noted that the period of generation of pulsed light, that is the time duration as from the timing of initiation of a given pulsed light beam until the initiation of the next pulsed light beam is termed the pulse radiation period.

As the laser device which becomes the light source for the laser oscillator 12, a solid laser capable of radiating pulsed light at a high repetition frequency is used.

As a laser medium of the solid laser, which becomes the light source of the laser oscillator 12, solid lasers, such as Nd/YAG laser, comprised of YAG (yttrium aluminum garnet) doped with Nd³⁺ ions, an Nd/YLF (yttrium lithium fluoride) or titanium/sapphire laser, is used. The second harmonics (wavelength: 532 nm), third harmonics (wavelength: 355 nm) or the fourth harmonics (wavelength: 266 nm) of the Nd/YAG laser may also be used. As the laser medium, compound semiconductors, obtained on synthesizing a compound composed of one or more of Ga, Al and In, and a compound composed of one or more of N, As, P, Zn, Se, Mg, Cd and S, such as GaN or GaAS, or compound semiconductors composed mainly of SiC or diamond, may be used.

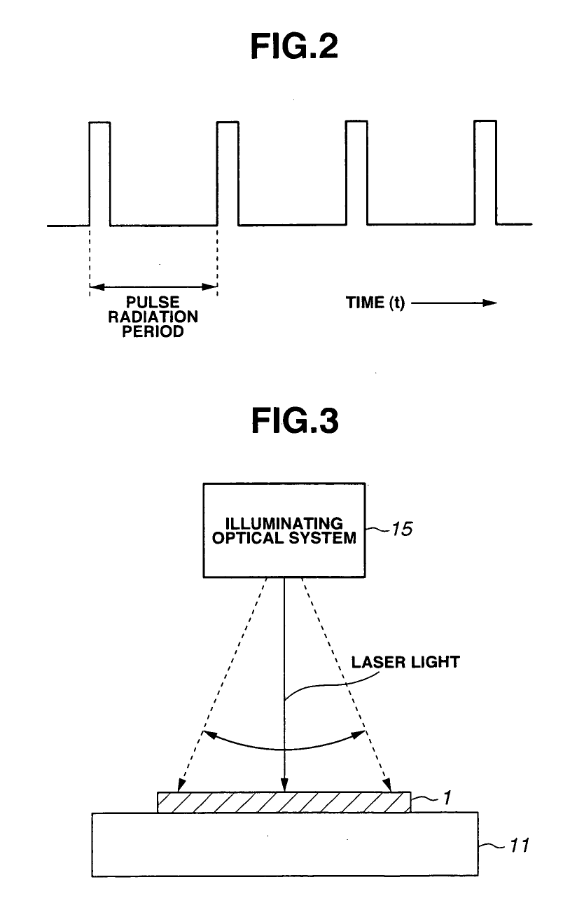

The pulse signal generator 13 is a circuit for controlling the radiation timing of the laser light pulses radiated from the laser oscillator 12. The pulse signal generator 13 generates pulse driving signals of the period of a predetermined time duration as shown in FIG. 2 to send the so generated pulsed driving signals to the laser device of the laser oscillator 12. In timed relationship to the pulse driving signals, the laser device radiates laser light pulses, that is, repeatedly radiates the laser light. Consequently, the radiation timing of the laser light from the laser oscillator 12 is controlled by these pulse driving signals.

The beam shaping optical system 14 trims the shape of the laser light, radiated from the laser oscillator 12, by way of beam shaping. The beam shaping optical system 14 includes e.g., a rectangular-shaped internal homogenizer for transforming the laser light beam radiated from the laser oscillator 12 into a rectangular-shaped beam. That is, the beam shaping optical system 14 trims the shape of the light spot of the laser light, illuminated on the TFT substrate 1, such as with a homogenizer. Meanwhile, the beam need not necessarily be rectangular, but may also be circular or linear, if so desired.

Moreover, the beam shaping optical system 14 homogenizes the distribution of light intensities of the laser light, such as with the homogenizer. That is, the beam shaping optical system 14 provides for uniform light intensities at each location within the light spot produced on illuminating the laser light on the TFT substrate 1.

The illuminating optical system 15 is an optical system on which the laser light radiated from the beam shaping optical system 14 is incident and which illuminates the incident laser light on the TFT substrate 1 on the movable stage 11.

The illuminating optical system 15 includes therein a galvano-scanner, made up by a galvanometer and a reflection mirror, an fθ lens for compensating the light distortion produced by the galvano-scanner, and a collimator lens for collimating the laser light on the TFT substrate 1. By e.g., the galvano-scanner, the illuminating optical system 15 reflects the incident laser light to illuminate the reflected light on the TFT substrate 1 on the movable stage 11, while linearly reciprocating the light spot of the illuminated laser light on the TFT substrate 1 within a predetermined extent, as shown in FIG. 3. Based on the control of the shifted position of the illuminated laser light spot by the illuminating optical system 15 and of the movement of the TFT substrate 1 by the movable stage 11, the laser annealing device 10 manages control to illuminate the laser light on the entire surface of the TFT substrate 1.

The controller 16 controls the pulse signal generator 13 to control the period or timing of pulse radiation by the pulse laser radiated from the laser oscillator 12. The controller 16 controls the operation of the movable stage 11 and the illuminating optical system 15 to control the movement of the light spot of the illuminated laser light on the TFT substrate 1.

The controlling operation of causing movement of the light spot of the illuminated laser light to effect annealing processing on the entire surface of the TFT substrate 1 is now explained. Meanwhile, the light spot of the laser light illuminated on the surface of the TFT substrate 1 is condensed to a size smaller than the size of the major surface of the TFT substrate 1.

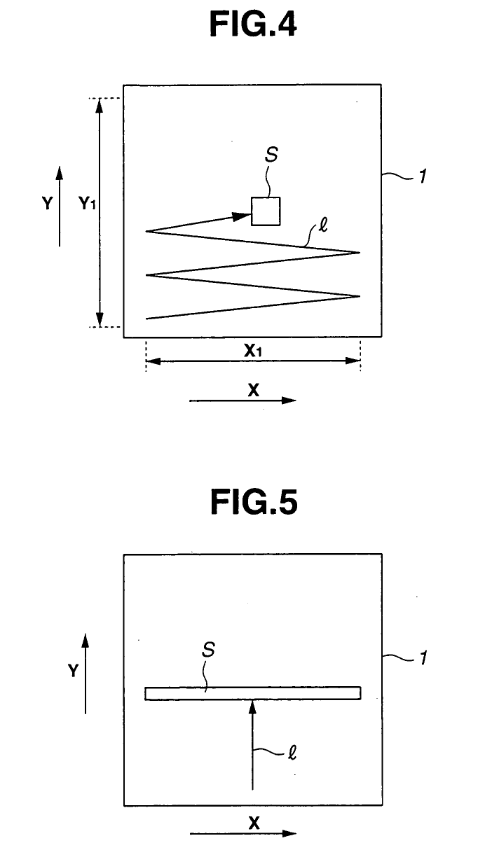

FIG. 4 schematically shows the trajectory of the illuminated light spot moved on the surface of the TFT substrate 1 during laser annealing. The laser annealing device 10 actuates the illuminating optical system 15 to cause linear reciprocating movement within a predetermined extent of the light spot S of the illuminated laser light on the TFT substrate 1. It is now assumed that the illuminated light spot S is reciprocated along one of the directions parallel to the major surface of the flat plate shaped TFT substrate 1, for example, an X direction in FIG. 4. It s also assumed that the range of the movement is that indicated by X1 in FIG. 4.

Moreover, the laser annealing device 10 causes reciprocating movement of the light spot S, as described above, at the same time as it causes movement of the movable stage 11 at e.g., a constant speed in a direction perpendicular to the direction of movement of the illuminated light spot S, for example, in a direction indicated Y in FIG. 4. The range of movement of the movable stage 11 is the range of movement of the illuminated light spot S from one end to the other end along the Y-direction of the TFT substrate 1, as indicated by the range Y1 of FIG. 4.

Thus, if the movable stage 11 and the illuminating optical system 15 are actuated simultaneously, the illuminated light spot S on the TFT substrate 1 is moved in a raster fashion on the surface of the TFT substrate 1, as indicated by a trajectory l in FIG. 4.

Thus in the laser annealing device 10, the laser light can be illuminated on the entire surface of the flat plate shaped TFT substrate 1, that is, the entire surface of the TFT substrate 1 can be annealed, by adjusting the movement speed of the movable stage 11 and the speed of the reciprocating movement of the illuminated light spot S depending on the size of the illuminated light spot S.

Although it is assumed that the illuminated light spot S has a rectangular profile, the illuminated light spot S may also be linear, as shown for example in FIG. 5. In this case, it is sufficient to cause the movement of the movable stage 11 at a constant speed, along the direction perpendicular to the longitudinal direction of the illuminated light spot S, such as along the direction Y in FIG. 5, without causing the illuminated light spot S to be reciprocate by e.g., a galvanometer by the illuminating optical system 15.

The radiation timing of the pulsed laser light is hereinafter explained.

The illuminated light spot S is raster-scanned over the entire surface of the illuminated light spot S of the TFT substrate 1, as described above. However, the laser light is radiated as pulsed light, and hence is not radiated at all times on the TFT substrate 1.

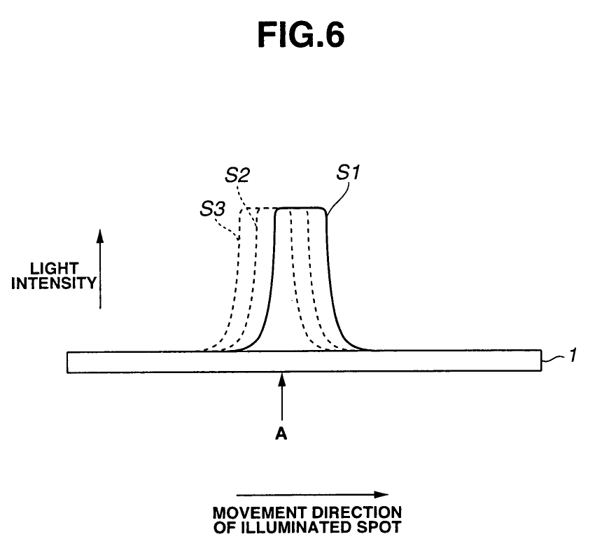

It is noted that, in the laser annealing device 10, the speed of the relative movement of the illuminated light spot S and the movable stage 11 is sufficiently retarded compared to the pulse radiation period by way of performing control so that the pulsed light radiated at an arbitrary timing is overlapped with the pulsed light radiated next. For example, referring to FIG. 6, the speed of relative movement between the illuminated light spot S and the movable stage 11 and the pulse radiation period are controlled so that the range of illumination of an illuminated light spot S1 of the pulsed light radiated at an arbitrary timing will be overlapped with that of an illuminated light spot S2 of the pulsed light radiated directly previously.

That is, in the laser annealing device 10, the period of radiation of the laser light and the speed of the relative movement between the illuminated light spot S and the movable stage 11 are controlled so that a succession of plural pulsed laser light beams will be illuminated on the same position on the TFT substrate 1. For example, a given position A along the movement direction of the illuminated light spot S is illuminated by a succession of three pulses, namely an illuminated light spot S1, radiated at an arbitrary timing, an illuminated light spot S2, radiated at a directly previous time point, and an illuminated light spot S3, radiated at a timing directly previous to the aforementioned directly previous time point, as shown in FIG. 6.

Furthermore, in the first embodiment, pulsed laser light is radiated at a shorter period than a preset pulse radiation period, referred to below as the a reference radiation period, so that the temperature of the TFT substrate 1 will be raised steadily in the course of the laser annealing.

This reference radiation period is now specifically explained. The reference radiation period will be explained taking an exemplary case of employing third harmonics of Nd:YAG (wavelength: 355 nm) as a light source.

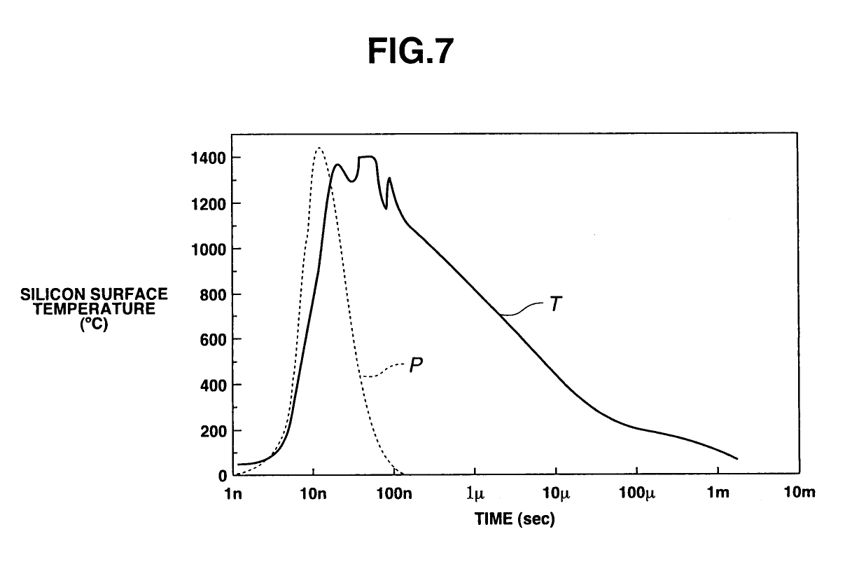

FIG. 7 is a graph showing temporal changes of the surface temperature at a location of the amorphous silicon illuminated by the laser light of the third harmonics of Nd:YAG. In FIG. 7, a dotted line P indicates temporal changes of the intensity of illumination of the first pulsed light beam, while a solid line T indicates temporal changes of the temperature of the silicon film surface illuminated by the pulsed light beam.

Referring to FIG. 7, each light pulse of the laser light of third harmonics of Nd:YAG has a pulse width of approximately 10 to 60 nsec. If this one light pulse is illuminated on the amorphous silicon film, the surface temperature at the illuminated position is raised to 1400° C., as indicated in FIG. 7. This temperature is higher than the temperature of melting of amorphous silicon. The surface temperature at the illuminated position is gradually lowered due to heat conduction or dissipation. The temperature decreasing ratio is acutely decreased at approximately 100 μsec and, after lapse of approximately one msec as from the start timing of the laser light, the temperature prior to the illumination of the laser light, such as ambient temperature, is reached.

The time interval as from the laser light radiation timing in illuminating one light pulse to the amorphous silicon film surface until the time the substrate temperature raised as a result of the laser light illumination reverts to the original substrate temperature is set as a reference radiation period. If the pulsed light of the third harmonics of Nd:YAG is illuminated on the amorphous silicon film with a pulse width of approximately 60 nsec, the reference radiation period is 1 msec. If the pulsed light is the third harmonics of Nd:YAG, the reference radiation period may be 100 μsec for which the temperature decreasing ratio is decreased acutely.

With the first embodiment of the laser annealing device 10, the laser light is radiated as light pulses in succession at a period shorter than the reference radiation period.

The surface temperature on the TFT substrate 1 in case the pulsed laser light radiated is of a period shorter than the reference radiation period is hereinafter explained.

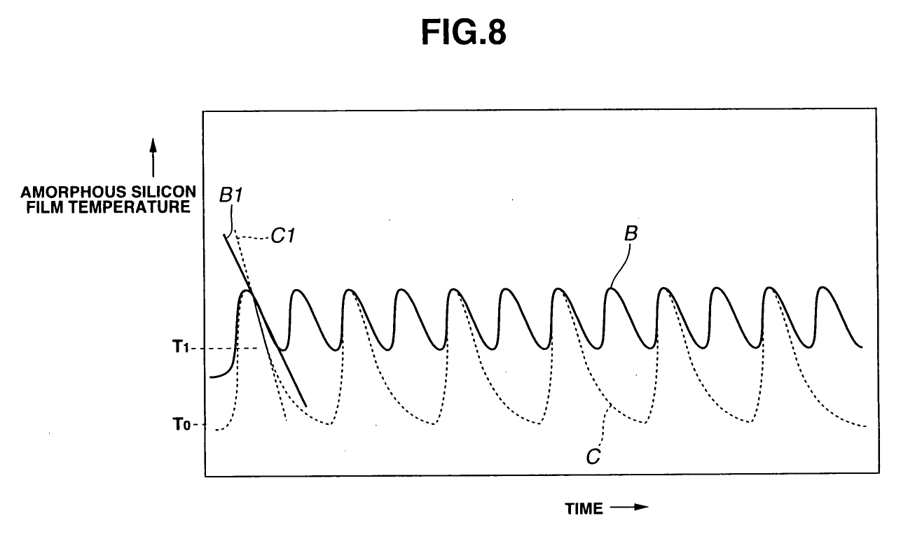

In FIG. 8, a solid line B indicates temporal changes of the temperature of the silicon film at an arbitrary position on the TFT substrate 1 in case pulses of the laser light are radiated in succession. In FIG. 8, the abscissa and the ordinate depict time and the surface temperature of the amorphous silicon film. Meanwhile, in FIG. 8, temporal changes of the temperature of the silicon film on the TFT substrate 1 in case the pulses of the laser light are radiated in succession at a period longer than the aforementioned reference radiation period are also shown by a dotted line C by way of comparison. Meanwhile, the temperature of the amorphous silicon film in an initial stage not illuminated by the laser light is indicated T0.

In case the pulses of the laser light are radiated in succession at a period shorter than the reference radiation period, the amorphous silicon film is illuminated, before the temperature raised due to a light pulse radiated at an arbitrary timing is cooled gradually completely, by a pulse temporally next following the light pulse radiated at the arbitrary timing, as shown by a solid line B in FIG. 8. Thus, if the light pulses are illuminated to a given location in succession, the temperature of the illuminated position is steadily a temperature T1 higher than the original substrate temperature T0 (T1>T0). That is, if the laser light is radiated as light pulses in succession, at a period shorter than the reference radiation period, such a state is reached which is similar to that in case laser annealing has been carried out as the substrate is heated by some heating means or other, such as a heater or a lamp.

If conversely the laser light is radiated as pulses in succession, at a period not less than the reference radiation period, a light pulse next to a given light pulse radiated at an arbitrary timing is illuminated on the amorphous silicon film after the temperature raised by the given light pulse has been gradually completely cooled, as indicated by a broken line C in FIG. 8. Thus, if the light pulses are illuminated in succession on an optional location, the illuminated location reverts to the original substrate temperature T0. That is, if the laser light pulses are radiated in succession at a period not less than the reference radiation period, such a state is reached which is similar to that in case laser annealing has been carried out as the substrate is heated by some heating means or other, such as a heater or a lamp.

If the temperature falling rate (amount of temperature decrease of the amorphous silicon film per preset time; tilt B1) in case the laser light is radiated as pulses in succession at a period shorter than the reference radiation period is compared to the temperature falling rate (tilt C1) in case the laser light is radiated as pulses in succession at a period not shorter than the reference radiation period, it may be seen that the tilt C1 is more moderate, as shown in FIG. 8.

That is, if the laser light is radiated as pulses in succession, at a period shorter than the reference radiation period, the temperature falling rate subsequent to temperature rise becomes smaller. That is, the cooling rate when silicon dissolved on heating is re-crystallized is slower so that it is possible to cause crystal growth to coarsen the particle size.

Thus, with the first embodiment of the laser annealing device 10, the laser light is radiated as pulses at a period shorter than the reference radiation period, while the position of the illuminated light spot S of the laser light on the surface of the substance is moved in a controlled manner so that the pulses of the laser light radiated will be illuminated a plural number of times on the same position on the surface of the TFT substrate 1. The reference radiation period is the time duration as from the radiation timing of one pulse of the laser light illuminated on the surface of the TFT substrate 1 until the substrate temperature raised by the illumination of the laser light reverts to the original substrate temperature.

Thus, with the first embodiment of the laser annealing device 10, the annealing processing may be carried out by a simplified structure, as the TFT substrate 1 has been raised in temperature, without providing separate heating means, such as an electrical heater or a lamp. Thus, with the first embodiment of the laser annealing device 10, it is possible to retard the cooling rate at the time of re-crystallization of silicon dissolved on heating, to coarsen the crystal grain of the polysilicon film and to provide for uniform crystal grain size distribution.

If, for example, the pulsed light of third harmonics of Nd:YAG is used as the laser light source and the amorphous silicon film is illuminated with a pulse width on the order of 10 to 60 nsec, it is advisable to radiate the laser light pulses every 25 μsec to 100 μsec. This range of the pulse width is preferred for the reason that, if the pulsed light of third harmonics of Nd:YAG is used as the laser light source, and the pulse radiation period is shorter than 25 μsec, the TFT substrate 1 is excessively heated and destroyed due to stored heat produced by laser light pulse illumination, due to excessively short laser light radiation interval, and that, if the pulse radiation period exceeds 100 μsec, the TFT substrate 1, heated due to laser light illumination, is cooled before the illumination of the next light pulse, because of the excessive laser light illumination interval, to render it difficult to heat the TFT substrate to a temperature higher than the temperature thereof prior to the annealing processing. For example, if, with the use of the aforementioned third harmonics of the pulsed light of Nd:YAG, the period of pulse radiation is set to 25 μsec (40 kHz), it is possible to heat the surface silicon temperature of the TFT substrate 1 to a temperature ranging between 200° C. and 400° C.

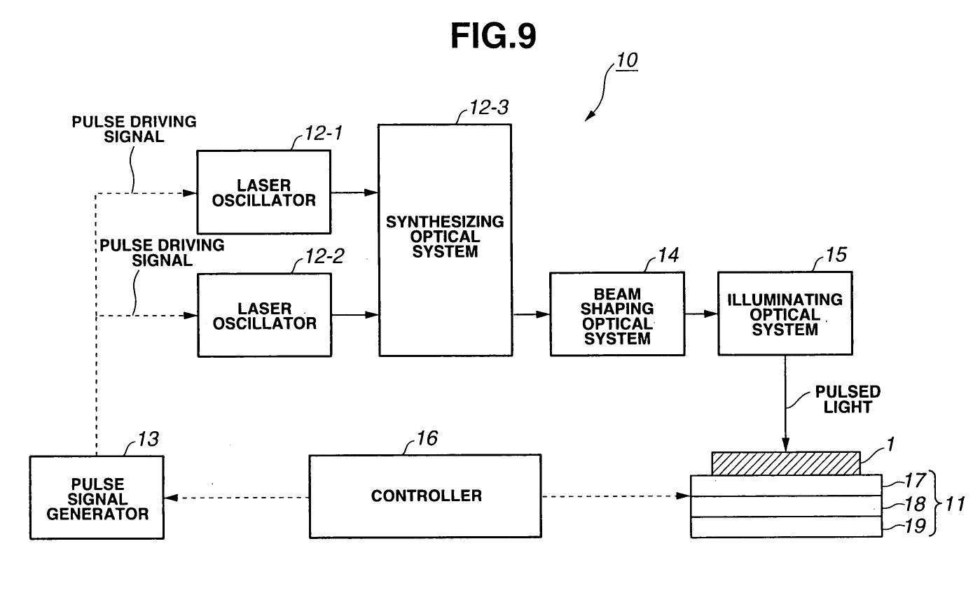

Meanwhile, if the laser oscillator uses a light source that is not able to radiate the pulsed light of a period shorter than the reference radiation period, it is sufficient to provide two laser oscillators 12.1 and 12.2 and a synthesizing optical system 12.3 for synthesizing the laser light radiated from the laser oscillators 12.1 and 12.2 and to cause the two laser oscillators 12.1 and 12.2 to radiate pulses out of phase by for example one period, as shown in FIG. 9. It is sufficient for the illuminating optical system 15 to illuminate a light beam synthesized from the two laser light beams on the TFT substrate 1.

Of course, three or more laser oscillators may be used, in which case the laser light pulses radiated from the laser oscillators are synthesized to illuminate the pulsed light of a higher period to the TFT substrate 1.

(Second Embodiment)

As a second embodiment of the present invention, a laser annealing device in which plural light pulses are synthesized to generate a synthesized pulsed laser light with an elongated pulse width and in which the resulting synthesized light is illuminated on a substance, is now explained.

Meanwhile, the present second embodiment of the laser annealing device is used in a polycrystallization step of forming a polysilicon film as a channel layer in the manufacturing process for a thin film transistor (TFT). That is, the present second embodiment of the laser annealing device is used in a step of illuminating the laser light on the amorphous silicon film formed on a glass substrate to effect annealing.

In the following explanation of the second embodiment of the laser annealing device, the component parts which are the same as those of the first embodiment of the laser annealing device are depicted by the same reference numerals and the detailed description therefor are omitted for simplicity.

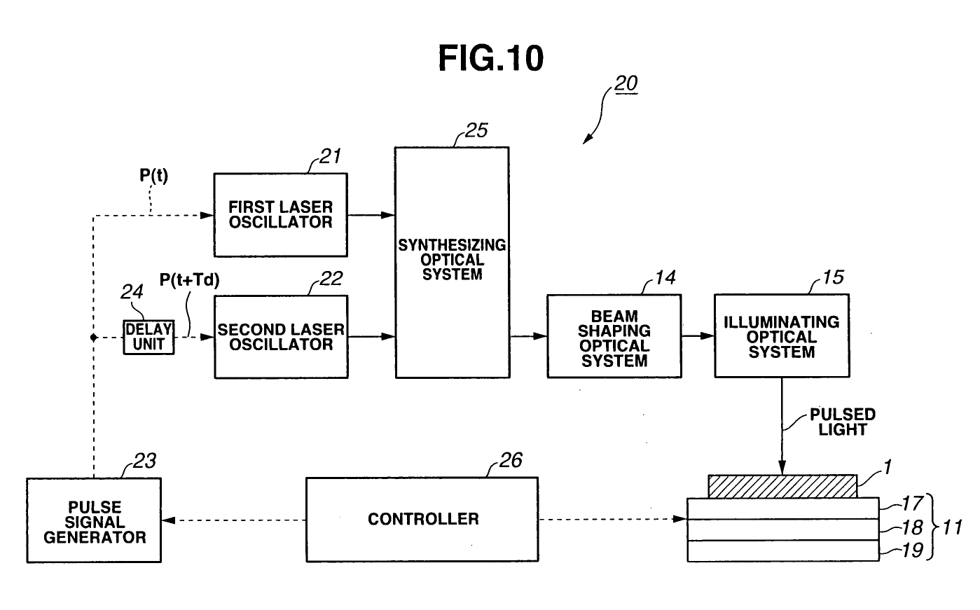

FIG. 10 shows the structure of a laser annealing device 20 of the second embodiment of the present invention. The laser annealing device 20 includes a movable stage 11, on which to set the TFT substrate 1 to be annealed, a first laser oscillator 21 for radiating laser light pulses, a second laser oscillator 22 for radiating laser light pulses, a pulse signal generator 23 for generating pulse driving signals of a preset period, a delay unit 24 for delaying pulse driving signals output from the pulse signal generator 23 a preset time, a synthesizing optical system 25 for synthesizing two laser light pulses radiated by the focusing servo laser oscillators 21, 22 to form a sole laser light pulse, a beam shaping optical system 14 for beam shaping the laser light radiated from the synthesizing optical system 25, an illuminating optical system 15 for illuminating the beam-shaped laser light to the TFT substrate 1 set on the movable stage 11, and a controller 26.

The first and second laser oscillators 21, 22 radiate laser light pulses for laser annealing the amorphous silicon film. Specifically, the first and second laser oscillators 21, 22 radiate pulsed laser light which repeats the sequence of alternate illumination and cessation of illumination every predetermined time interval.

As the laser devices, operating as light sources for the first and second laser oscillators 21, 22, the solid laser capable of radiating laser light pulses at a high repetition period is used. The medium of the solid laser, used as the light source for the first and second laser oscillators 21, 22, is similar to that of the laser oscillator 12 used in the first embodiment.

The pulse signal generator 23 is a circuit for controlling the radiation timing of the laser light pulses from the first and second laser oscillators 21, 22. Similarly to the pulse signal generator 13 of the first embodiment, the pulse signal generator 23 generates pulse driving signals of a period of a predetermined time interval to send these driving signals to the laser devices of the first and second laser oscillators 21, 22.

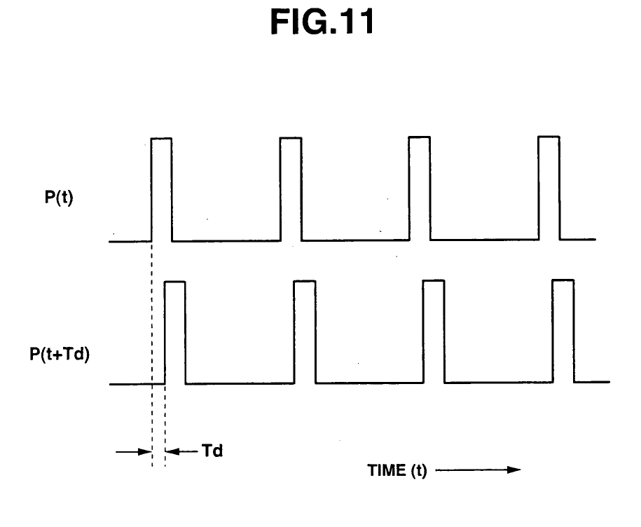

The pulse driving signals, supplied to the second laser oscillator 22, are delayed by a predetermined time Td by the delay unit 24. That is, the first laser oscillator 21 is supplied with non-delayed pulse driving signals P(t), while the second laser oscillator 22 is supplied with pulse driving signals P(t+Td) delayed by time Td. Referring to FIG. 11, showing the waveform, the first laser oscillator 21 is supplied with pulse driving signals P(t), in which light pulses are generated at a predetermined period, while the second laser oscillator 22 is supplied with pulse driving signals P(t+Td), in which light pulses of the same period as P(t) but delayed a preset time Td are generated repeatedly. The laser devices of the first and second laser oscillators 21, 22 radiate laser light pulses in succession in timed relationship to the pulse driving signals P(t) and P(t+Td). Thus, the first and second laser oscillators 21, 22 radiate pulses which are of the same repetition frequency but in which the pulse generating timing is out of phase from one light pulse to another.

The synthesizing optical system 25 synthesize the two light beams, radiated from the first and second laser oscillators 21, 22, on the same optical axis.

The beam shaping optical system 14 trims the beam shape of the synthesized light radiated from the synthesizing optical system 25. The beam shaping optical system 14 also provides for a uniform distribution of the light intensity of the synthesized light beam by e.g., a homogenizer.

The illuminating optical system 15 is supplied with the laser light radiated from the beam shaping optical system 14 to illuminate the incident laser light on the TFT substrate 1 on the movable stage 11.

The controller 26 controls the pulse signal generator 23 and the delay unit 24 to control the pulse radiation period or the pulse radiation timing of the pulsed laser radiated from the laser oscillator 12. The controller 26 also controls the operation of the movable stage 11 and the illuminating optical system 15 to perform movement control of the illuminated laser light spot on the TFT substrate 1.

The control operation of causing movement of the illuminated laser light spot to effect annealing processing for the entire surface of the TFT substrate 1 is hereinafter explained.

The operation of the movable stage 11 and the illuminating optical system 15 of the laser annealing device 20 of the second embodiment is the same as that of the movable stage 11 and the illuminating optical system 15 of the above-described first embodiment. That is, the laser annealing device 20 of the second embodiment controls the movable stage 11 and the illuminating optical system 15 so that the illuminated light spot S will be moved in a raster fashion on the surface of the TFT substrate 1. Thus, with the laser annealing device 20, the laser light can be illuminated on the entire surface of the flat plate shaped TFT substrate 1 by adjusting the speed of movement of the movable stage 11 and the speed of the reciprocating movement of the illuminated light spot S depending on the size of the illuminated light spot S. That is, the entire surface of the TFT substrate 1 can be annealed.

The control timing of the laser light pulse radiation by the second embodiment of the laser annealing device 20 is hereinafter explained.

As in the first embodiment, described above, the laser annealing device 20 performs control so that, by retarding the speed of relative movement between the illuminated light spot and the movable stage 11 sufficiently as compared to the pulse radiation period, the pulsed light radiated at a given timing will be overlapped with the pulsed light radiated next. However, in the second embodiment, two laser oscillators are provided and, although the detailed des will be made subsequently, the two light pulses radiated by the two laser oscillators are synthesized to generate a sole synthesized pulsed light beam. Thus, in the present second embodiment, the speed of relative movement of the illuminated light spot and the movable stage 11 and the pulse radiation period are controlled in such a manner that the range of illumination of an optional synthesized pulsed light beam and that of the synthesized pulsed light beam radiated at the next timing will be overlapped with each other.

The synthesis of these two pulsed light beams is now explained specifically.

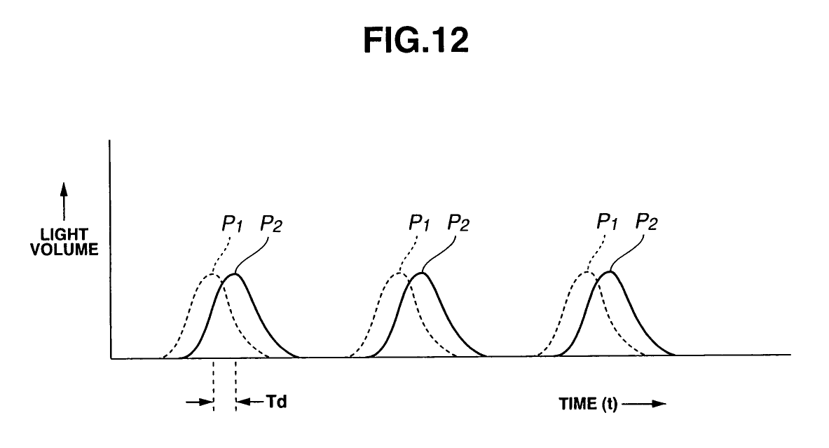

The laser light illuminated by the laser annealing device 20 to the TFT substrate 1 is the light synthesized from the laser light radiated from the first laser oscillator 21, referred to below as the first laser light, and the laser light radiated from the second laser oscillator 22, referred to below as the second laser light. The first laser light and the second laser light are the same in the period of generation of the pulsed light, however, are phase-shifted relative to each other by the delay unit 24, with the amount of the phase deviation being controlled so that the light emission of the second laser light will be initiated before the emission of an arbitrary pulse of the first laser light comes to a close. That is, the radiation timing of the first laser light (dotted line P1) is offset with respect to that of the second laser light (dotted line P2) so that the illumination time durations of the first and second laser light beams will be temporally overlapped with each other, as shown in FIG. 12.

By offsetting the radiation timings of the first and second laser light beams relative to each other, the two pulsed laser light beams are synthesized by the synthesizing optical system 25 to generate a synthesized laser light pulse longer than the pulse width of one light pulse by a time equal to the delay time.

That is, with the laser annealing device 20 of the second embodiment of the present invention, the time duration of illumination of the amorphous silicon film by one light pulse may be elongated by synthesizing two light pulses.

Thus, with the present second embodiment of the laser annealing device 20, it is possible to elongate the time until the substrate temperature raised by illumination of one light pulse reverts to the original substrate temperature, so that it is possible to slow down the rate of cooling following the melting on cooling to coarsen the crystal grain size.

Moreover, with the laser annealing device 20, in which it is possible to elongate the pulse width of one light pulse, the speed of relative movement of the illuminated light spot S may be raised even in case plural light pulses are illuminated in succession on the same location on the TFT substrate 1, with the consequence that the entire surface of the TFT substrate 1 can be annealed speedily.

In addition, with the laser annealing device 20 of the second embodiment of the present invention, in which solid laser is used as the light source for the laser oscillators 21, 22, the output timing of the pulsed light can be controlled to a high accuracy of, for example, 10 nsec or less, with the result that the location of generation of the pulsed light of the synthesized light, generated on synthesizing the first and second laser light beams, may be controlled to a high accuracy.

For a case of generating the synthesized light using two excimer lasers as a light source of the laser light and a case of generating the synthesized light using the solid laser as the light source as in the case of the laser annealing device 20, the synthesized light pulses and changes in silicon temperature are now scrutinized.

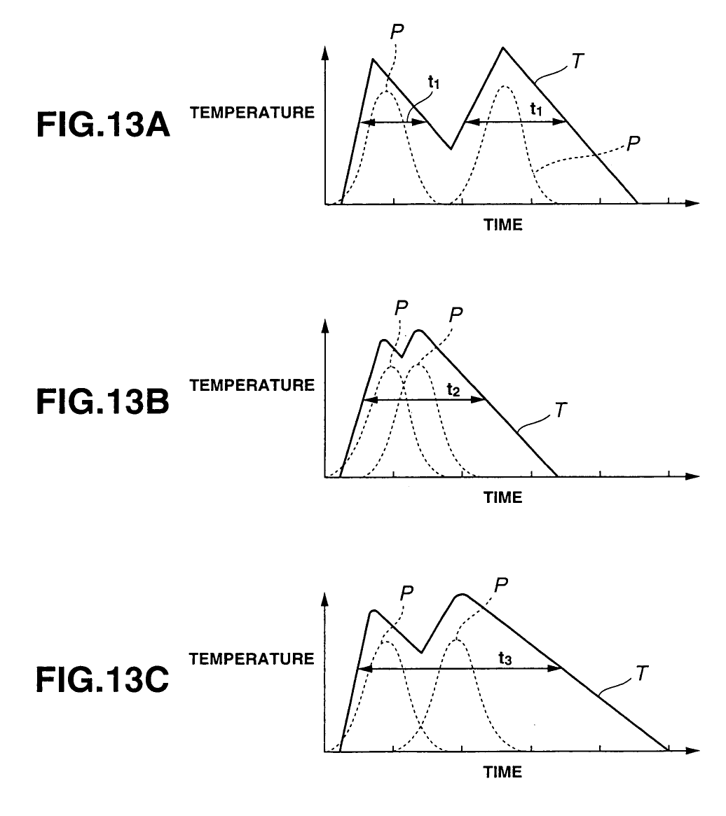

In FIGS. 13A to 13C, the time elapsed as the temperature of the amorphous silicon film is changed, the output timing of the pulsed laser light beams from two laser light sources and the time duration of illumination of the synthesized pulsed light, are plotted on the abscissa, and the temperature of the amorphous silicon film is plotted on the ordinate. In FIGS. 13A to 13C, the time durations, indicated by arrows t1, t2 and t3, denote the time duration of melting by heating of the amorphous silicon film by the synthesized pulsed light. In addition, in FIGS. 13A to 13C, a dotted line P depicts temporal changes of the illumination intensity of the pulsed light. In FIGS. 13A to 13C, a solid line T depicts time changes of the temperature of the amorphous silicon film. The time width of the pulsed light for both the excimer laser and the solid laser is on the order of tens of nsec.

In case of laser annealing with the excimer laser, it is difficult to control the output timing of the pulsed laser light from two laser light sources to high accuracy, such that an error on the order of 100 nsec is produced. As a consequence, the output timing offset in outputting pulsed laser light beams from the two laser light sources is increased or decreased to give the synthesized pulsed light of FIGS. 13A and 13B. Specifically, in FIG. 13A, the offset in the light emission timing of the two laser light beams is slow such that the two laser light pulses are not synthesized into a synthesized light pulse but are illuminated separately on the amorphous silicon film. In FIG. 13B, the offset in the light emission timing of the two laser light beams is fast such that the synthesized pulsed light illuminates the amorphous silicon film only for a short time.

If the processing of laser annealing is performed using a solid laser, it is possible to control the output timing of the pulsed laser light beams of the two laser light sources to high accuracy, so that the timing variations in outputting the pulsed laser light beams from the two laser light sources may be reduced to 10 nsec or less. With the pulse width of, for example, tens of nsec, the two pulsed laser light beams can be synthesized in stability, as shown in FIG. 13C. It is also seen that the time t3 of heating the amorphous silicon film for melting in case the laser annealing processing is carried out using the solid laser is longer than the time t1 or t2 of heating the amorphous silicon film for melting with the use of the excimer laser.

Thus, it turns out that the synthesized pulsed laser light can hardly be generated using plural excimer lasers, and that, if the synthesized pulsed laser light is generated using plural solid lasers, the timing control can be managed to high accuracy.

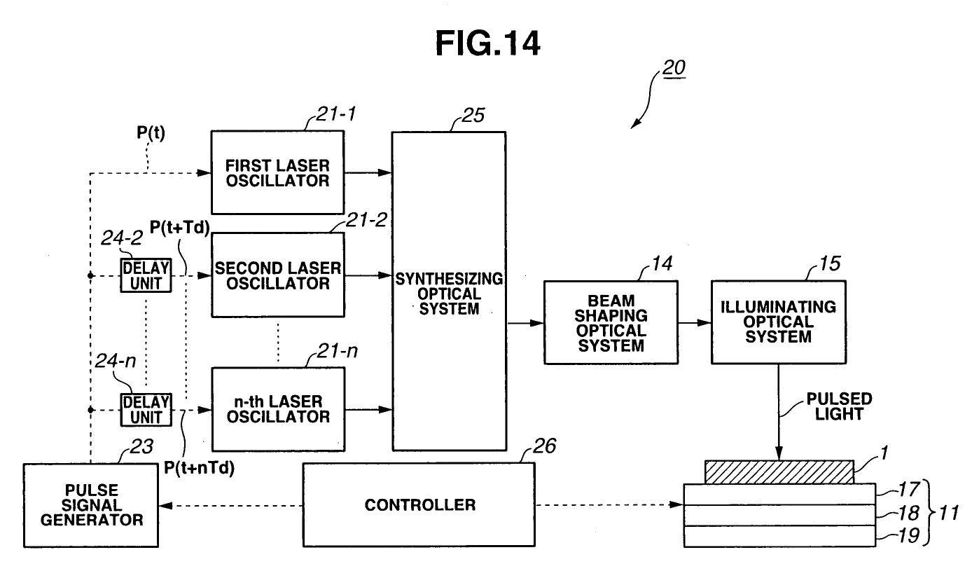

In the foregoing, an example of a laser annealing device having two laser oscillators has been illustrated. However, as shown for example in FIG. 14, the laser annealing device 20 of the second embodiment may also be provided with three of more laser oscillators, instead of the two laser oscillators.

In this case, the pulsed driving signals, supplied to the respective laser oscillators, need to be offset by respective different delay values. For example, with the delay amount Td of the second laser oscillator, the delay values of the second and third laser oscillators are set to respective different values of (2×Td) and (3×Td), respectively.

Meanwhile, in the laser annealing device 20, the two light pulses to be synthesized together may be the same in intensity, or the preceding light pulse may be of higher intensity. By increasing the intensity of the preceding light pulse, the cooling rate may be smoother to coarsen the grain size of the yielded crystals.

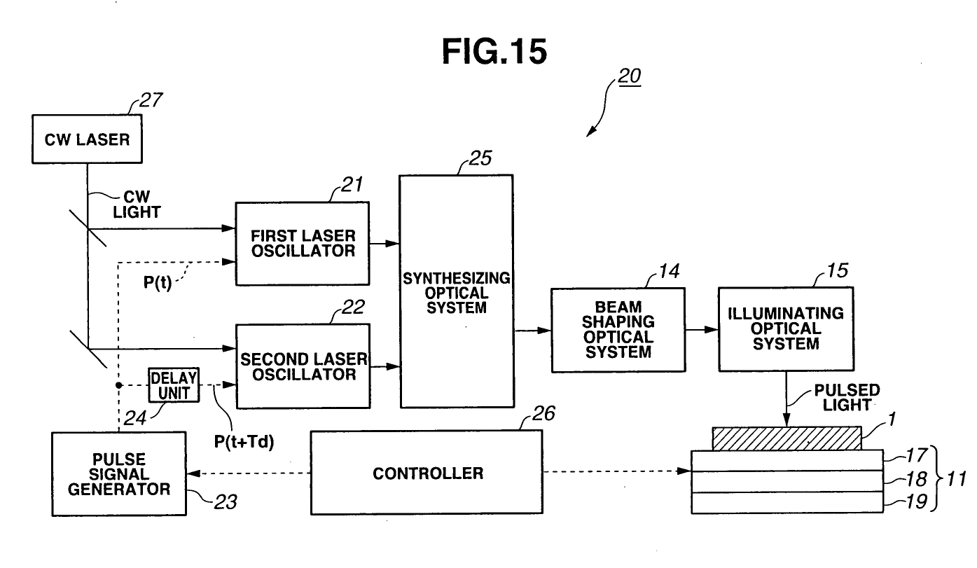

With the laser annealing device 20, the first and second laser oscillators 21, 22 may be formed by a device capable of generating stabilized pulsed light by so-called injection seeding. The injection seeding, shown in FIG. 15, is a method for generating the pulsed laser light of the system which provides for stabilized light amplification on opening a Q-switch by injecting a continuous wave (CW) laser 27 of a constant light intensity as a fundamental laser. As the source of the CW laser, which is the fundamental laser, a stable continuous wave light source, such as a diffraction grating feedback type semiconductor laser or an Nd:YAG laser, is used. By generating the pulsed laser light by this injection seeding, the radiation timing of the pulsed light can be controlled to be several nsec or less.

The above-described second embodiment of the present invention may also be combined with the first embodiment. That is, plural light pulses may be synthesized to give a sole light pulse, as the period of the synthesized light pulse is set so as to be shorter than the reference radiation period used in the first embodiment.

(Third Embodiment)

As a third embodiment of the present invention, such a laser annealing device in which it is possible to control the position of generation of crystal nuclei of a polysilicon film is hereinafter explained.

It should be noted that the laser annealing device of the third embodiment is used in a polycrystallization process for forming the polysilicon film, as a channel layer, in the manufacturing process for a thin film transistor (TFT). That is, the laser annealing device of the third embodiment is used in a step of illuminating the laser light on the amorphous silicon film formed on the glass substrate.

In the following explanation of the laser annealing device of the third embodiment, the same reference numerals as those used in the explanation of the laser annealing device 10 of the first embodiment are used, and the detailed description thereof is omitted for simplicity.

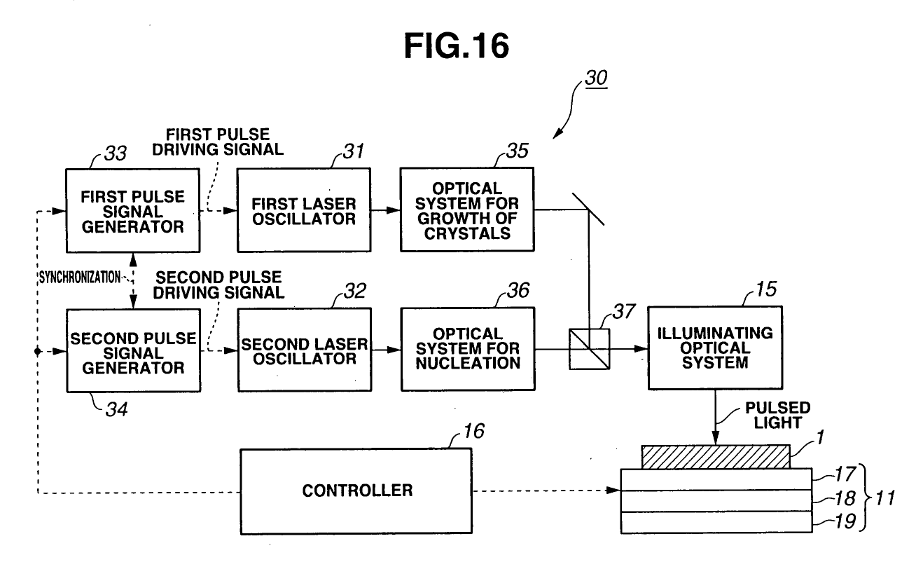

FIG. 16 shows the structure of a laser annealing device 30 according to the third embodiment of the present invention. The laser annealing device 30 includes a movable stage 11, on which to set the TFT substrate 1 to be annealed, a first laser oscillator 31 for radiating laser light pulses, a second laser oscillator 32 for radiating laser light pulses, a first pulse signal generator 33 for generating first pulse driving signals of a predetermined period, a second pulse signal generator 34 for generating first pulse driving signals of a predetermined period, an optical system for growth of crystals 35 for providing a uniform intensity distribution of the laser light radiated from the first laser oscillator 31, an optical system for nucleation 36 for providing nonuniform intensity distribution of the laser light radiated from the second laser oscillator 32, a synthesizing optical system 37 for synthesizing the laser light radiated from the optical system for growth of crystals 35 and the laser light radiated from the optical system for nucleation 36 together to form a sole laser light beam, an illuminating optical system 15 for illuminating the laser light radiated from the synthesizing optical system 37 to the TFT substrate 1 set on the movable stage 11, and a controller 38.

The first and second laser oscillators 31, 32 radiate laser light for laser annealing the amorphous silicon film. The first and second laser oscillators 31, 32 radiate light pulses. That is, the first and second laser oscillators 31, 32 radiate pulsed laser light. Specifically, the first and second laser oscillators 31, 32 radiate pulsed laser light beams which repeat the sequence of alternate illumination and cessation of illumination every predetermined time interval.

The laser device, used as a light source for the each of the first and second laser oscillators 31, 32, is a solid laser capable of illuminating light pulses at a high repetition frequency. The medium of the solid laser, used as the light source for the first and second laser oscillators 31, 32, is similar to that of the laser oscillator 12 used in the first embodiment.

The first pulse signal generator 33 is a circuit for controlling the radiation timing of the laser light pulses from the first laser oscillator 31. Similarly to the pulse signal generator 13 of the first embodiment, the pulse signal generator 33 generates pulse driving signals of a period of a predetermined time interval to send these driving signals to the laser device of the first laser oscillator 31.

The second pulse signal generator 34 is a circuit for controlling the radiation timing of the laser light pulses from the second laser oscillator 32. Similarly to the pulse signal generator 13 of the first embodiment, the pulse signal generator 34 generates pulse driving signals of a period of a predetermined time interval to send these driving signals to the laser device of the second laser oscillator 32.

Meanwhile, the first pulse signal generator 33 and the second pulse signal generator 34 are driven in a timed relationship to each other to control the radiation timing of the pulsed light radiated from the first laser oscillator 31 and that of the pulsed light radiated from the second laser oscillator 32 in a timed relationship to each other. The second pulse driving signals, output from the second pulse signal generator 34, are of the same period as and delayed a predetermined time from the first pulse driving signals output from the first pulse signal generator 33. Thus, the first and second laser oscillators 31, 32 radiate pulses which are the same in period but which are out of phased in pulse generating timings from each other. The dephasing value of pulsed light radiated from the first and second laser oscillators 31, 32 will be explained later in detail.

The optical system for growth of crystals 35 performs the processing of beam shaping and homogenizing the intensity distribution of the laser light radiated from the first laser oscillator 31. The optical system for growth of crystals 35 includes an internal homogenizer and, by this homogenizer, trims the beam of the laser light to a circular or a rectangular shape. That is, the optical system for growth of crystals 35 homogenizes the shape of the illuminated light spot, produced on illuminating the laser light on the TFT substrate 1, to a circular or a rectangular shape. In addition, the optical system for growth of crystals 35 provides for uniform light intensity distribution of the laser light.

The laser light, homogenized in light intensity distribution by the optical system for growth of crystals 35, is used for crystal growth on the occasion of the annealing processing. This laser light will be explained in detail subsequently.

The optical system for nucleation 36 performs the processing of trimming the shape of the laser light radiated from the second laser oscillator 32 and heterogenizing the light intensity distribution. The optical system for growth of crystals 35 includes an internal homogenizer for trimming the shape of the laser light to the same shape as the beam trimmed by the optical system for growth of crystals 35. That is, the optical system for nucleation 36 trims the shape of the light spot of the laser light illuminated on the TFT substrate 1. Additionally, the optical system for nucleation 36 provides for non-uniform light intensity distribution of the laser light on the TFT substrate 1 by e.g., the above-mentioned homogenizer and the optical mask. That is, the optical system for nucleation 36 provides for a predetermined intensity distribution of the light spot of the laser light illuminated on the TFT substrate 1 to a predetermined light intensity distribution.

The laser light, the light intensity distribution of which has been heterogenized by the optical system for nucleation 36, is used for generating nuclei on the occasion of performing the annealing processing. This laser light will be discussed in detail subsequently.

The synthesizing optical system 37 synthesizes two light beams, namely a light beam radiated from the optical system for growth of crystals 35 and a light beam radiated from the optical system for nucleation 36, on the same optical axis, such as with a beam splitter.

The illuminating optical system 15 is supplied with the laser light, radiated from the synthesizing optical system 37, to illuminate the incident laser light on the TFT substrate 1.

The controller 38 controls the first pulse signal generator 33 and the second pulse signal generator 34 to control the pulse radiation period or the pulse radiation timing of a pulse laser radiated from the first laser oscillator 31 and the second laser oscillator 32. The controller 38 also controls the operation of the movable stage 11 and the illuminating optical system 15 to control e.g., the illuminating position of the laser light on the TFT substrate 1.

The operation of the movable stage 11 and the illuminating optical system 15 in the laser annealing device 30 of the third embodiment is hereinafter explained.

The operation of the movable stage 11 and the illuminating optical system 15 in the laser annealing device 30 of the third embodiment is the same as that of the movable stage 11 and the illuminating optical system 15 of the first embodiment described above. That is, the laser annealing device 30 of the third embodiment controls the movable stage 11 and the illuminating optical system 15 so that the illuminated light spot S will be moved in a raster fashion on the surface of the TFT substrate 1. Consequently, with the laser annealing device 30 of the third embodiment, the laser light can be illuminated on the entire surface of the flat plate shaped TFT substrate 1 by adjusting the speed of movement of the movable stage 11 and the speed of the reciprocating movement of the illuminated light spot S. That is, the entire surface of the TFT substrate 1 can be annealed.

The laser light, the light intensity distribution of which has been homogenized by the optical system for growth of crystals 35, and the laser light, the light intensity distribution of which has been heterogenized by the optical system for nucleation 36, are hereinafter explained.

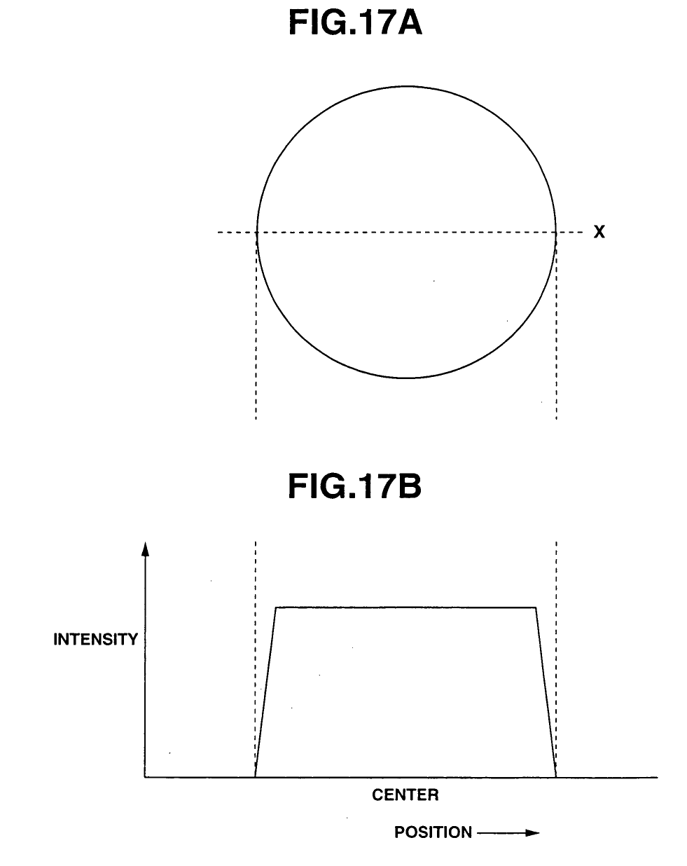

The laser light, the light intensity distribution of which has been homogenized by the optical system for growth of crystals 35, exhibits the intensity distribution as shown for example in FIGS. 17A and 17B. FIG. 17A schematically shows the light spot of the laser light, trimmed by the optical system for growth of crystals 35 and illuminated on the TFT substrate 1. FIG. 17B shows the light intensity at each position of a straight line passing through the center of the illuminated light spot, for example, a straight line X in FIG. 17A. The laser light, which has traversed the optical system for growth of crystals 35, has its beam profile and light intensity adjusted in this manner so that the light intensity will be the same from one position in the light spot to another.

The laser light, having the intensity distribution uniformed in this manner by the optical system for growth of crystals 35, is used for inducing crystal growth in the course of laser annealing. The pulsed light, emitted from the optical system for growth of crystals 35, is termed below the pulsed light for inducing crystal growth.

Although the beam shape is circular in FIGS. 17A and 17B, the beam shape may also be rectangular or linear.

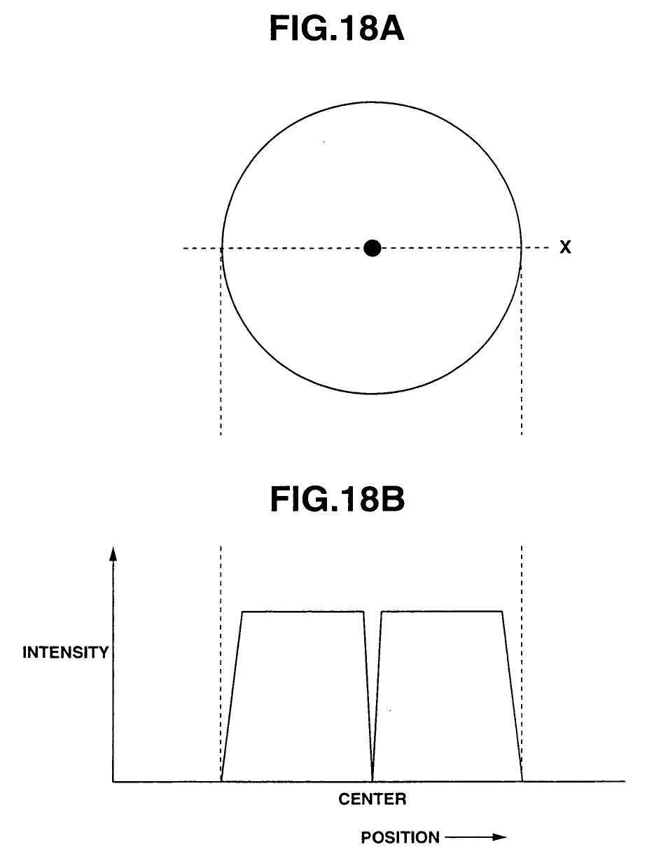

The laser light the light intensity distribution of which has been heterogenized by the optical system for nucleation 36, exhibits the intensity distribution as shown for example in FIGS. 18A and 18B. FIG. 18A schematically shows the light spot of the laser light, beam-shaped by the optical system for nucleation 36 and illuminated on the TFT substrate 1. FIG. 18B shows the light intensity at each position on a straight line passing through the center of the illuminated light spot of FIG. 18A, such as a straight line Xo.

The optical system for nucleation 36 transforms the beam profile of an input laser light beam to a shape approximately equal to the beam shape of the optical system for growth of crystals 35. Simultaneously, the optical system for nucleation 36 processes the laser light so that a portion of the area exhibiting the uniformed light intensity distribution will present appreciably different intensity value. The optical system for nucleation 36 processes the input laser light to set the intensity of a minor sized region near the center of the illuminated light spot to approximately zero as well as to set the intensity of the area other than the minor sized region to an optional uniform intensity, as shown for example in FIGS. 18A and 18B.

For appreciably lowering the intensity of a portion within the illuminated light spot, it is sufficient to cause a beam to pass through e.g., a homogenizer to homogenize the intensity of the beam in its entirety to then cause the so homogenized laser light to pass through an optical mask having a light transmitting member a portion of which is applied an opaque paint or member. Such optical mask is provided at a conjugate position with respect to a collimator lens adapted for condensing the laser light oil the TFT substrate 1.

The laser light, the intensity distribution of which has been heterogenized by the optical system for nucleation 36, is used for nucleation at the time of laser annealing. The pulsed light, radiated from the optical system for nucleation 36, is referred to below as the pulsed light for nucleation.

Although the beam shape is circular in FIGS. 18A and 18B, the beam shape may also be rectangular or linear, in conjunction with the optical system for growth of crystals 35.

Meanwhile, in FIGS. 18A and 18B, only one minor sized area is provided in an area with uniform intensity distribution. Alternatively, two of such minor sized areas may be provided instead of one. In the example shown in FIGS. 18A and 18B, the intensity of the minor sized area is lower than in the area with uniform intensity distribution. However, in the present invention, it is sufficient that the intensity of the minor sized area is appreciably different from that of the area with uniform intensity distribution. That is, the intensity of the minor sized area may be set so as to be higher.

The control timing of pulse radiation of the laser light of the laser annealing device 30 of the third embodiment is now explained.

In the laser annealing device 30, as in the first embodiment, the speed of relative movement between the illuminated light spot and the movable stage 11 is set so as to be sufficiently lower than the pulse radiation period to cause the pulsed light radiated at an optional timing to be superposed on the pulsed light radiated next. It is noted that, in the third embodiment, there are provided two laser oscillators. If only one of the laser oscillators is in operation, control is managed so that the pulsed light radiated at an arbitrary timing will be overlapped with the pulsed light radiated next.

The laser light radiated from the laser annealing device 30 to the TFT substrate 1 is the light synthesized from the laser light radiated from the first laser oscillator 21 and the laser light radiated from the second laser oscillator 22. The first laser light and the second laser light are equal in pulse generating period, but are out of phase a preset time relative to each other.

Specifically, in the third embodiment, control is managed so that, after the pulsed light is radiated from the second laser oscillator 32, the pulsed light is radiated from the first laser oscillator 31.

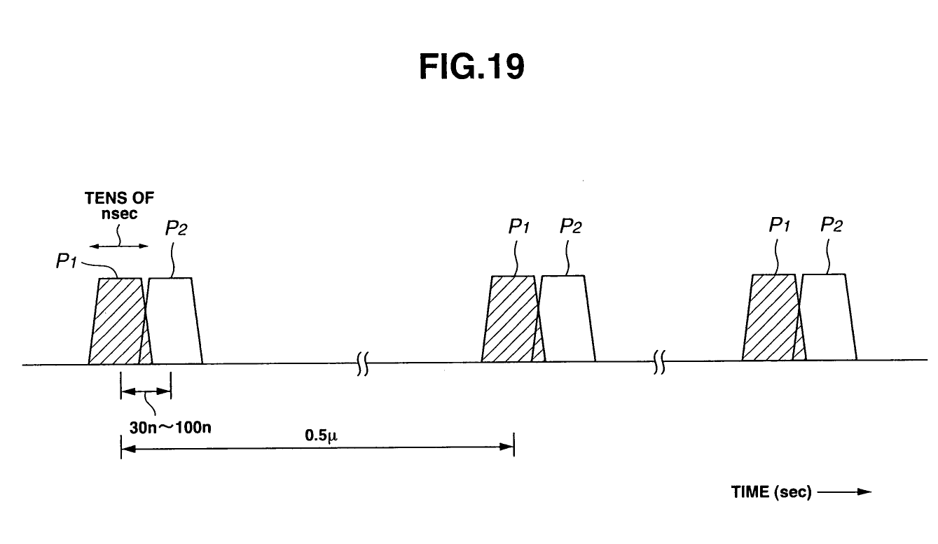

That is, a light pulse P1 for nucleation of FIG. 18 is first illuminated, and subsequently a light pulse P2 for inducing the crystal growth of FIG. 17 is illuminated, on substantially the same illumination position on the TFT substrate 1, as shown in FIG. 19.

For example, if the laser light of third harmonics of Nd:YAG is used as a light source, with the pulse width thereof being tens of nsec, the periods of the light pulse P1 for nucleation and the period of the light pulse P2 for inducing the crystal growth are preferably set to approximately 0.5 μsec, for the time offset of approximately 30 to 100 nsec as from the time of illumination of the light pulse P1. for nucleation until the time of illumination of the light pulse P2 for inducing the crystal growth.

If the light pulse P1 for nucleation is illuminated to an optional illuminating position on the TFT substrate 1, the probability of generation of crystal nuclei in the minor sized area with a variable intensity becomes higher.

It is specifically well-known that, if, when amorphous silicon is to be transformed into polysilicon by laser annealing, the area with significant intensity change of the illuminated laser light is compared to the area with only small change in intensity, the probability of generation of the crystal nuclei is higher in the area with significant changes in the laser light intensity. That is, the probability of the generation of crystal nuclei is higher in the rim area of the illuminated light spot or in the minor-sized area where the intensity of the pulsed light P1 for nucleation is markedly low.

Thus, by illuminating the light pulse P1 for nucleation on the TFT substrate 1, first of all, it is possible to control the position of the crystal nuclei generated.

The pulsed light P1 for nucleation and the light pulse P2 for inducing the crystal growth are illuminated in this order on an arbitrary illuminating position. This uniformly dissolves the portion where the crystal nuclei have been generated, and the near-by area, with the so generated crystal nuclei then undergoing the crystal growth.

Thus, with the laser annealing device 30, when the laser light is illuminated at an arbitrary position of the TFT substrate 1, the light pulse P1 for nucleation is first illuminated to generate crystal nuclei and the light pulse P2 for inducing the crystal growth with homogenized intensity distribution is then illuminated to allow control of the location of generation of crystal nuclei as well as to induce the growth of the generated crystal nuclei.

Thus, by controlling the position of generation of crystal nuclei and then inducing the crystal growth, it is possible to coarsen and homogenize the crystal grain size by the following reason:

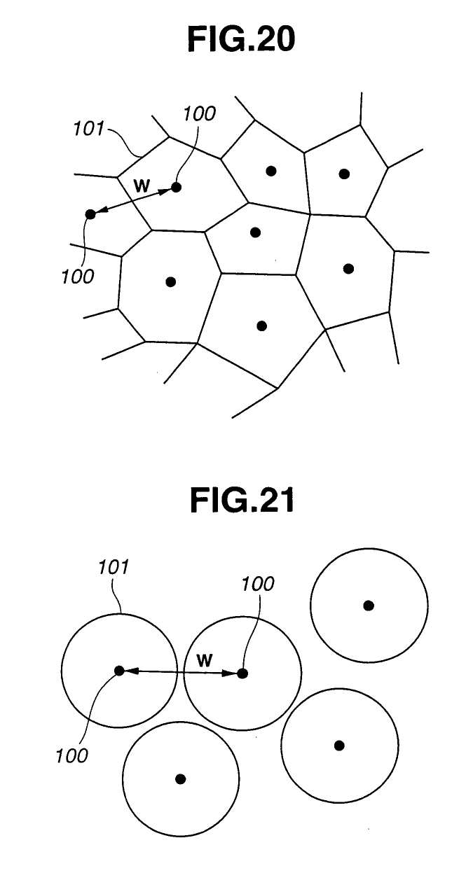

The crystal grain size of a polysilicon film is thought to differ depending on whether the crystal nuclei generated at an initial stage of re-crystallization is dense or sparse. For example, if the separation W between neighboring crystal nuclei 100 is small, as shown in FIG. 20, the crystal boundary surfaces 101 collide against one another in the course of growth of the respective crystals, so that no further crystal growth is not permitted. If conversely the separation W between neighboring crystal nuclei 100 is long, as shown in FIG. 21, the crystal boundary surfaces 101 do not collide against one another in the course of growth of the respective crystals, so that crystal growth to a larger grain size is allowed.

Thus, with the laser annealing device 30 of the third embodiment of the present invention, in which it is possible to control the location of generation of crystal nuclei, as well as to homogenize the crystal grain size.

Moreover, if the location of generation of the crystal nuclei can be controlled in this manner, the boundary surfaces between neighboring crystals may be formed along the centerline of the gate electrode interconnections of the bottom gate type TFT substrate 1. Specifically, crystal nuclei are generated along the edges on both sides of the gate electrode interconnections. In this case, crystal growth occurs from both side edges of the interconnections so that crystals generated collide against each other at a mid portion of the interconnections. Thus, crystal boundary surfaces are formed as a ridge along the centerline of the interconnections. By forming the crystal boundary surfaces along the centerline of the interconnections, the interconnecting portions between the interconnections and the crystal boundary surfaces are diminished to lower the resistivity to improve electrical characteristics.

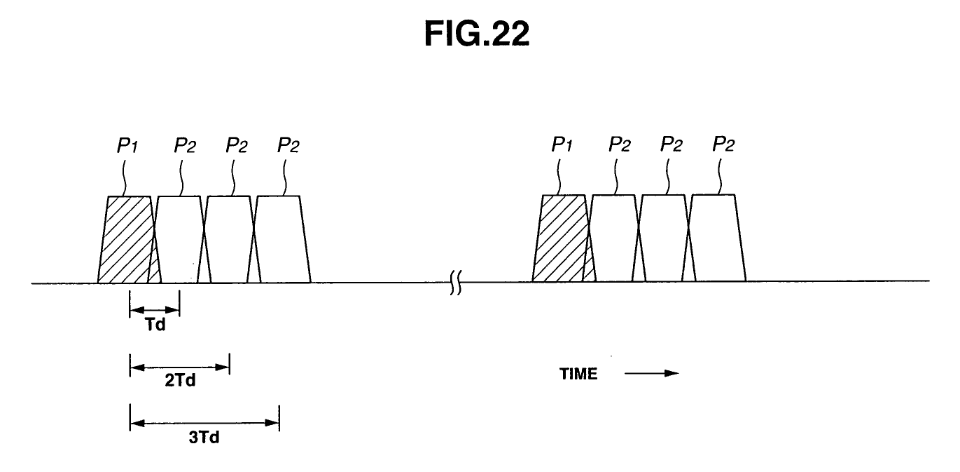

As the third embodiment of the laser annealing device 30, an example provided with two laser oscillators has been illustrated in the foregoing. The third embodiment of the laser annealing device may, however, be provided with three or more laser oscillators, instead of only one. In this case, the laser oscillators are preferably offset with respective different delay values. For example, with the delay amount Td of the second laser oscillator, the delay values of the third and fourth laser oscillators are set to respective different values of (2×Td) and (3×Td), respectively. In FIG. 22, preferably the leading pulse is the light pulse P1 for nucleation and the next following pulses are all light pulses P2 for inducing the crystal growth.

It is also possible for the first and second laser oscillators 31, 32 of the laser annealing device 30 to generate a pulse laser stabilized by so-called injection seeding, as indicated in the second embodiment.

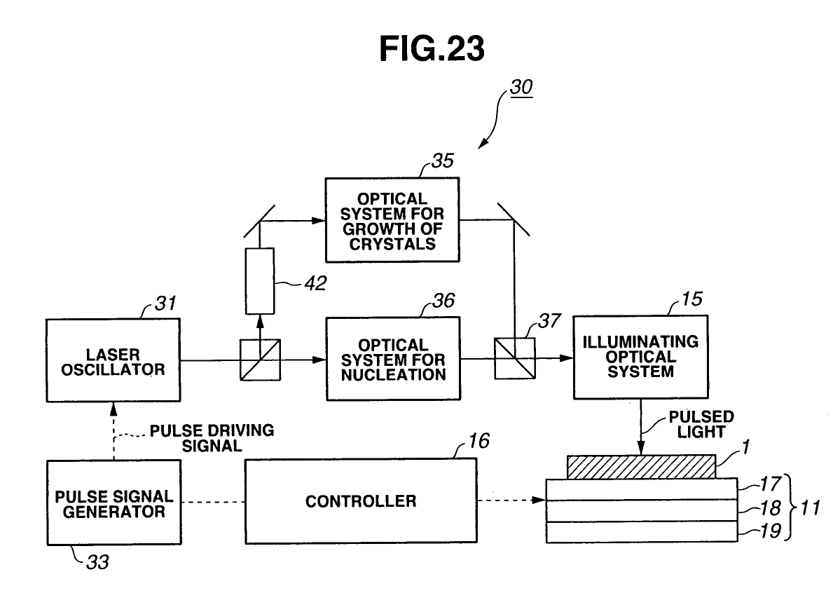

In the laser annealing device 30 of the third embodiment of the present invention, the light pulse P1 for nucleation light pulse P2 for inducing the crystal growth are generated by two laser oscillators. Alternatively, two laser light beams may also be generated using a sole laser oscillator, as shown in FIG. 23. In this case, the laser light generated by the sole laser oscillator may be split by for example a polarizing beam splitter 41 to generate two laser light beams, one of which is input to the optical system for growth of crystals 35 and the other of which is input to the optical system for nucleation 36. It is necessary in this case to delay the light input to the optical system for growth of crystals 35 by for example an optical fiber 42 to generate time offset of a predetermined time.

(Fourth Embodiment)

As a fourth embodiment of the present invention, the method for manufacturing a thin film transistor (TFT) is explained.

The manufacturing method for the thin film transistor, explained as the fourth embodiment of the present invention, is the manufacturing method for a thin film transistor having a so-called bottom gate type structure (bottom gate type TFT). This bottom gate type TFT has a structure in which a gate electrode, a gate insulator and a polysilicon film (channel layer) are sequentially deposited on e.g., a glass substrate, beginning from the lower layer. That is, this bottom gate type TFT means such a TFT in which the gate electrode is provided between the polysilicon film as a channel layer and the glass substrate.

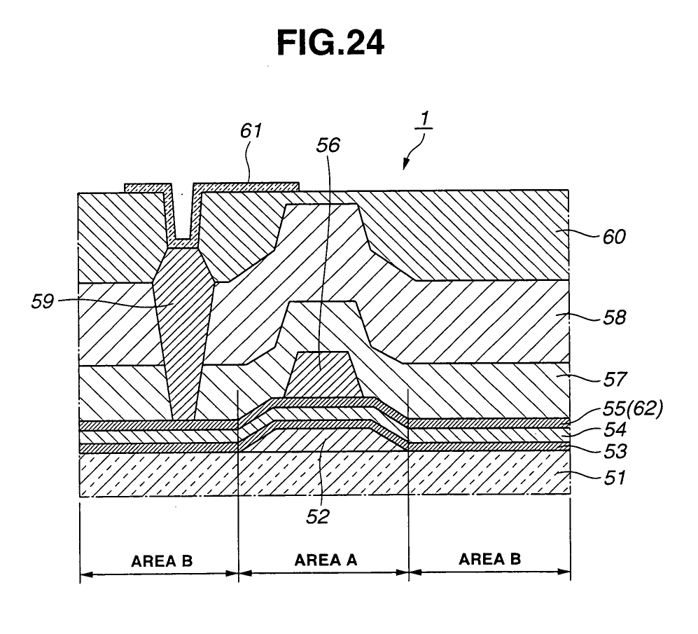

The specified structure and manufacturing method of the bottom gate type TFT, arranged as described above, is now explained with reference to FIG. 24.

A bottom gate type TFT1 is made up by a gate electrode 52, a first gate insulating film 53, a second gate insulating film 54, a polysil icon film 55, a stopper 56, a first inter-layer insulating film 57, a second inter-layer insulating film 58, a wiring 59, a planarized film 60 and a transparent electrically conductive film 61, on the glass substrate 51, as shown in FIG. 24.

For manufacturing the bottom gate type TFT1, a film of a metal for an electrode, such as molybdenum (Mo), aluminum (Al), tantalum (Ta), titanium (Ti), chromium (Cr) or tungsten (W), is first formed on a glass substrate 51. The so formed metal film then is anisotropically etched and patterned to form the gate electrode 52. This gate electrode 52 is locally formed on the glass substrate. An area of the glass substrate where the gate electrode 52 has been formed is termed an area A, while an area thereof where the gate electrode 52 has not been formed is termed an area B.

The first gate insulating film 53 formed e.g., of silicon nitride (SiNₓ) is then deposited on the glass substrate 51 where the gate electrode 52 has been formed.

The second gate insulating film 54 formed e.g., of silicon dioxide (SiO₂) is then deposited on the first gate insulating film 53.

The polysilicon film 55, formed of polysilicon, is then deposited on the second gate insulating film 54. This polysilicon film 55 functions as a channel layer of the bottom gate type TFT1.

For forming the polysilicon film 55, an amorphous silicon film 62 is formed on the second gate insulating film 54 by for example the LPCVD (Low Pressure Chemical Vapor Deposition) method. The laser light is illuminated on the so formed amorphous silicon film 62 to heat and dissolve the amorphous silicon film 62 for re-crystallization.

An impurity for forming a source/drain area is ion-doped to the polysilicon film 55. The stopper 56 is provided at this time so that no impurities are doped to the portion of the polysilicon film 55 overlying the gate electrode 52.

The first inter-layer insulating film 57 of, for example, SiO₂, is layered on the polysilicon film 55 on which the stopper 56 has been formed.

The second inter-layer insulating film 58 of, for example, SiNₓ, is deposited on the first inter-layer insulating film 57.

A contact hole for contacting the source/drain area of the polysilicon film 55 then is bored and a metal film of for example aluminum (Al) or titanium (Ti) is formed. The so formed metal film is patterned, such as by etching, to form the wiring 59. This wiring 59 interconnects the source/drain area of the respective transistors formed on the polysilicon film 55 to form a predetermined circuit pattern on the substrate.

For planarizing the surface of the bottom gate type TFT1, a planarized film 60 of, for example, an acrylic resin, is formed on the second inter-layer insulating film 58, carrying the wiring 59 thereon.

For connecting the wiring 59 to an external terminal, the transparent electrically conductive film 61 is then formed on the planarized film 60.

With the above-described structure of the bottom gate type TFT1, the electrical field mobility of the channel layer becomes very high because the channel layer is formed of polysilicon. Thus, by using the bottom gate type TFT1, the high definition and the high speed as well as the small size of the display may be achieved.

A laser annealing device 70, used for the laser annealing process in generating the polysilicon film 55, is hereinafter explained.

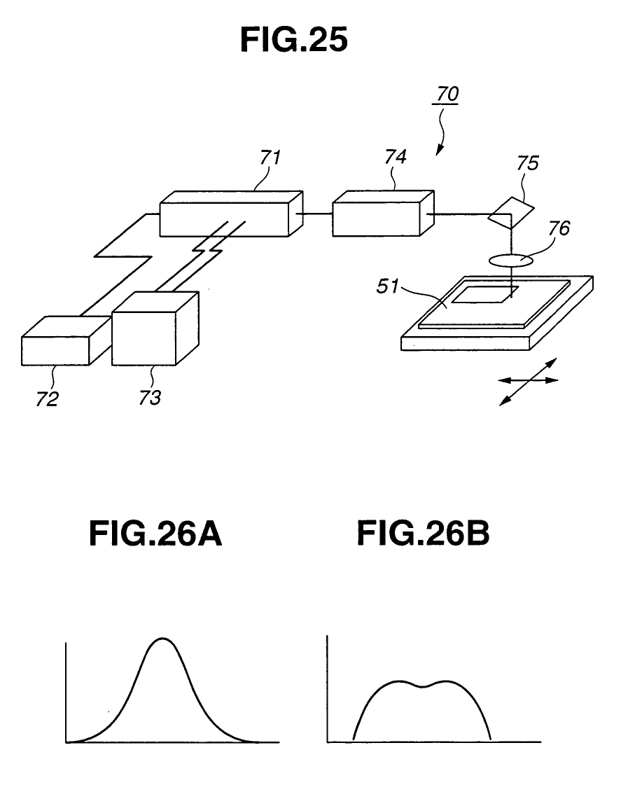

FIG. 25 shows an illustrative structure of the laser annealing device 70, used for the laser annealing process in generating the polysilicon film 55. This laser annealing device 70 performs laser annealing processing, using the laser light of a solid laser or a semiconductor laser, exhibiting stable light intensity from one pulse to the next, in order to form the polysilicon film 55 having a homogeneous crystal grain size, in the bottom gate type TFT1 employing in particular the bottom gate type structure.

This laser annealing device 70 includes a laser oscillator 71, a laser driving power supply 72, a cooling device 73, a homogenizer 74, a mirror 75, a projection lens 76 and a movable stage 77.

The laser oscillator 71 is a pulse laser light source radiating the laser light of a solid laser, such as Nd:YAG or Nd:YLF. The laser oscillator 71 also sometimes uses a semiconductor laser, such as GaN semiconductor laser, as the laser light to be radiated. The laser oscillator 71 receives the driving power for laser oscillation from the laser drivingpower supply 72. Moreover, the laser oscillator 71 is connected to the cooling device 73, so that the cooling medium supplied from the cooling device 73 flows around the laser oscillator for cooling.

The laser oscillator 71 transforms the Nd:YAG laser, with a wavelength of 1064 nm, into second harmonics (with a wavelength of 532 nm), third harmonics (with a wavelength of 355 nm) and into fourth harmonics (with a wavelength of 266 nm), by way of wavelength conversion. The laser oscillator 71 also transforms the Nd:YAG laser, with a wavelength of 914 nm, into second harmonics (with a wavelength of 457 nm), by way of wavelength conversion. Moreover, the laser oscillator 71 transforms the Nd:YLF laser, with a wavelength of 1046 nm, into second harmonics (with a wavelength of 523 nm), third harmonics (with a wavelength of 349 nm) and into fourth harmonics (with a wavelength of 262 nm), by way of wavelength conversion. Additionally, the laser oscillator 71 transforms the laser light of the GaN semiconductor laser, with a wavelength of 380 to 450 nm, by way of wavelength conversion.

The homogenizer 74 shapes the laser light radiated from the laser oscillator 71 into the laser light of a predetermined wavelength, shape and intensity. There are occasions where the homogenizer 74 is unified to the laser oscillator 71. The homogenizer 74 shapes the Gaussian laser light, shown for example in FIG. 26A, radiated from the laser oscillator 71, to top hat shaped laser light shown in FIG. 26B.

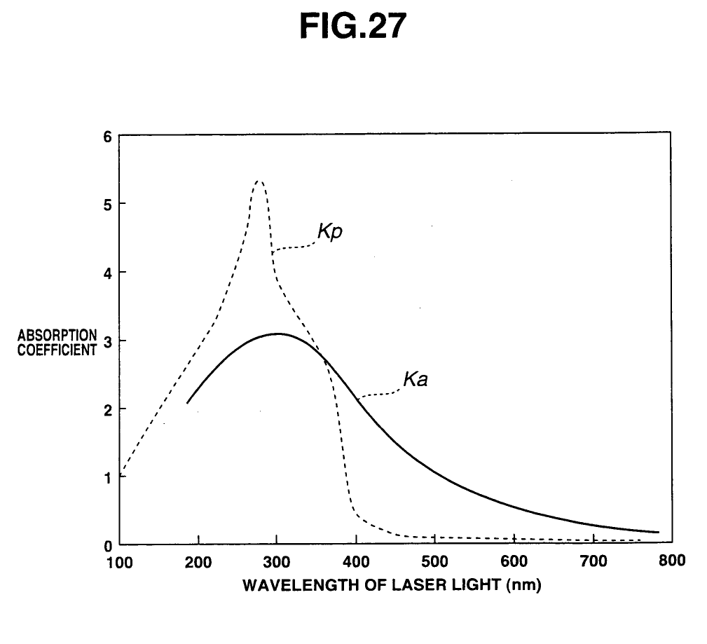

It should be noted that, with the wavelength radiated to the amorphous silicon film 62 of 250 nm or less, high output laser light cannot be generated, whereas, with the wavelength not less than 550 nm, the absorption coefficient of the amorphous silicon film 62 becomes smaller to prove a hindrance to shift to polysilicon, as shown in FIG. 27. For this reason, the oscillation frequency of the laser oscillator 71 is limited to not less than 250 nm and to not higher than 550 nm. In FIG. 27, a dotted line Kp stands for the light absorption coefficient by polysilicon and a solid line Ka stands for the light absorption coefficient by amorphous silicon.

The mirror 75 is arranged on the laser light radiating side. On this mirror falls the laser light shaped by the homogenizer 74. This mirror 75 also reflects the incident laser light towards a projecting lens 76.

The projecting lens 76 condenses the incident laser light to project the light onto the amorphous silicon film 62 in the bottom gate type TFT1.

The movable stage 77 is a stage for supporting the glass substrate 51 and includes the function of moving the glass substrate 51, as an object of light illumination, to a predetermined position. Specifically, the movable stage 77 is made up by an X-stage, a Y-stage and an absorbing plate.

The X- and Y-stages are movable in the horizontal direction. The glass substrate 51, as an object for illumination, is moved in two mutually orthogonal directions, between these X- and Y-stages, to a predetermined location. Thus, with the laser annealing device 70, it is possible to laser-anneal part or all of the surface of the glass substrate 51.

A Z-stage is movable in a vertical direction for adjusting the stage height. That is, the Z-stage is movable along the optical axis of the illuminated laser light, in other words, along a direction perpendicular to the substrate surface.

It should be noted that the laser annealing device, used in the laser annealing step in generating the polysilicon film 55, may not be the the device shown in FIG. 25, but may be a laser annealing device of any of the first to third embodiments described above. In this case, however, the wavelength of the laser annealing device is not less than 250 nm and not longer than 550 nm.

A first illustrative application in the manufacturing method for the thin film transistor according to the present invention is now explained.

In the first illustrative application, the laser light radiated from the laser oscillator 71 is the Nd:YAG laser. This Nd:YAG laser is a third harmonics with a wavelength of 355 nm, with the energy being 0.5 mj/pulse and with the repetition frequency of 1 kHz. Moreover, with this Nd:YAG laser, it is possible to control the light intensity variations from pulse to pulse to 5% or less.

There are occasions where the Nd:YAG laser is radiated based on for example the Model 210S•355•5000 of Lightwave Electronics Inc. of USA.

The laser annealing device 70 radiates the aforementioned laser light, radiated from the laser oscillator 71, to the amorphous silicon film 62, at an energy density of approximately 400 mj/cm², at a rate of 10 to 100 pulses per one site. Since the amorphous silicon film 62 has an absorption coefficient to the laser light of the wavelength of 355 nm which is of a relatively large value of approximately 2.8, substantially the totality of light incident on the amorphous silicon film 62 is absorbed by the amorphous silicon film 62 and is consumed for heating and dissolving the amorphous silicon.

That is, in this first illustrative application, in which the solid laser capable of controlling pulse-based variations in light intensity to 5% or less is illuminated, it is possible to form the polysilicon film 55 having a uniform crystal grain size as compared to the case of using an excimer laser exhibiting pulse-based light intensity variations of nearly 10% to allow manufacture of a thin film transistor exhibiting stable characteristics.

In the present illustrative application, employing a solid laser, exhibiting only small light intensity variations, it is possible to reduce the difference in the reached temperatures of the amorphous silicon film 62. Thus, in a thin film transistor, employing the bottom gate type structure, it is possible to further homogenize the grain size of polysilicon generated to decrease the number of rejects to improve the yield. In the present illustrative application, employing the solid laser, in distinction from the case of utilizing the excimer laser, exchange of deteriorated charged gases is unneeded to improve the production efficiency or to reduce the production cost.

A second illustrative application in the manufacturing method for a thin film transistor according to the present invention is hereinafter explained.

The present second illustrative application differs from the first illustrative application in controlling the film thickness of the amorphous silicon film to a preset range responsive to the wavelength of the illuminated laser light.

If, with the amorphous silicon film 62, the transmittance of the illuminated laser light is not higher than 2%, temperature rise of the gate electrode in the region A cannot be expected to occur, so that it is not possible to achieve the favorable effect of the present invention in resolving the difference in the reached temperatures in the regions A and B. On the other hand, with transmittance not less than 20%, temperature rise in the amorphous silicon film 62 cannot be expected to occur, while temperature rise in the gate electrode 52 is significant. There is also the possibility that the difference between the reached temperature of the amorphous silicon film 62 and the cooling rate following laser illumination is increased. Thus, the amorphous silicon film 62 is formed to a thickness such that, depending on the wavelength of the laser light illuminated, the transmittance of the laser light is not less than 2% and not larger than 20%.

The following Table 1 illustrates the film thicknesses of the amorphous silicon film such that, for various values of the wavelengths of the laser light, the transmittance is not less than 2% and not larger than 20%.

TABLE 1

| light source | absorption | pressure of | pressure of |
|---|---|---|---|
| wavelength | coefficients of | amorphous silicon | amorphous silicon |
| (nm) | amorphous silicon | film (nm) T = 2% | film (nm) T = 20% |
| 266 | 2.85 | 29.1 | 12.0 |
| 355 | 2.8 | 39.5 | 16.2 |
| 405 | 2.1 | 60.0 | 24.7 |
| 457 | 1.48 | 96.1 | 39.5 |
| 532 | 0.9 | 184.0 | 75.7 |

For example, if the wavelength of the illuminated laser light is 355 nm, and the film thickness of the amorphous silicon film is controlled to 16.2 nm, transmittance is 20%. If the film thickness of the amorphous silicon film is controlled to 39.5 nm, transmittance is 20%. That is, if, in illuminating the laser light of 355 nm, transmittance is to be suppressed to not less than 2% and not larger than 20%, the film thickness of the amorphous silicon film needs to be controlled to a range from 16.2 nm to 39.5 nm.

The volume of light transmitted through the amorphous silicon film 62 is given by the following equation:

I/I₀=exp(−4πkd/λ)

where I is the volume of transmitted light, I₀ is the volume of incident light, k is an absorption coefficient, d is a film thickness of the amorphous silicon film and λ is the wavelength of the illuminated laser light.

For example, if the wavelength of the illuminated laser light is 355 nm, the film thickness of the amorphous silicon film is controlled to approximately 30 nm, approximately 5% of the light volume of the incident laser light is transmitted through the amorphous silicon film 62 without absorption thereby. The laser light transmitted through the amorphous silicon film 62 is transmitted through the first gate insulating film 53 and the second gate insulating film 54 transparent to the wavelength of the laser light.

The laser light transmitted through the first gate insulating film 53 in the region A carrying the gate electrode 52 is absorbed by the gate electrode 52 to contribute to temperature rise of the gate electrode 52. The laser light transmitted through the first gate insulating film 53 in the region B not carrying the gate electrode 52 is further transmitted through the glass substrate 51 so as to be absorbed by the movable stage 77.

That is, since the laser light transmitted through the first gate insulating film 53 in the area A heats only the gate electrode 52 to raise its temperature, the difference in temperature between the amorphous silicon film 62 formed in the area A and the gate electrode 52 is diminished. This prevents heat from being transferred from the amorphous silicon film 62 to the gate electrode 52 to reduce the difference in the temperature of the amorphous silicon film 62 reached or in the cooling rate following laser illumination between the areas A and B. Thus, in a thin film transistor employing the bottom gate type structure in particular, the crystal grain size of the polysilicon film generated may be further homogenized to lower the rate of occurrence of rejects.

The second illustrative application may also be implemented by a structure as now explained. In this structure, the Nd:YLF laser is used as a solid laser radiated from the laser oscillator 71. This Nd:YLF laser is a second harmonics of a wavelength of 523 nm, with the energy and the repetition frequency of 6 mj/pulse and 5 kHz, respectively. Moreover, with this Nd:YLF laser, pulse-based light intensity variations may be controlled to be 6% or less. The Nd:YLF laser may occasionally be radiated based on for example the Evolution-30 of Positive Light Inc., USA.

It turns out from the above Table that, with the wavelength of approximately 523 nm, the absorption coefficient of the amorphous silicon film 62 is approximately 0.9. On the other hand, if the transmittance is to be suppressed to not less than 2% and not larger than 20%, the film thickness of the amorphous silicon film needs to be controlled to be in a range from 75.7 nm to 184.0 nm, so that, in the present structure, the amorphous silicon film is formed so that its film thickness will be 100 nm.

Under these conditions, 12% of the volume of the laser light incident on the amorphous silicon film 62 is transmitted through the amorphous silicon film 62. The laser light, transmitted through the amorphous silicon film 62, is transmitted through the second gate insulating film 54, transparent to the wavelength of the laser light, and through the first gate insulating film 53.

The laser light transmitted through the first gate insulating film 53 in the area A provided with the gate electrode 52 is absorbed by the gate electrode 52 to contribute to temperature rise of the gate electrode 52. The laser light transmitted through the first gate insulating film 53 in the area B not provided with the gate electrode 52 is further transmitted through the glass substrate 51 so as to be absorbed by the movable stage 77.

It is possible in this manner to reduce the difference in the temperature of the amorphous silicon film 62 reached and in the cooling rate following laser illumination between the areas A and B. In particular, it is possible to provide for uniform crystal grain size of the polysilicon film generated in the bottom gate type TFT1 employing the bottom type structure.

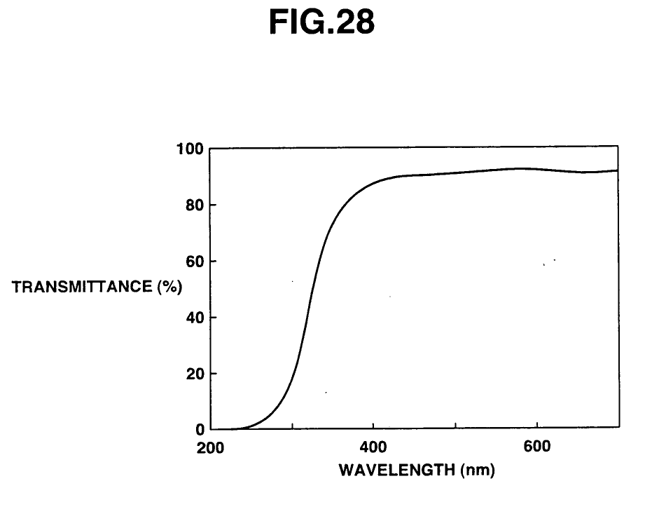

The graph of FIG. 28 shows transmittance characteristics of the glass substrate 51 for respective wavelengths of the illuminated laser light. As may be seen from FIG. 28, the transmittance of the laser light through the glass substrate 51 becomes lower with decreasing wavelengths.

That is, in the area B, if the laser light transmitted through the first gate insulating film 53 is of a short wavelength, the laser light is not transmitted through the glass substrate 51 but is absorbed thereby so as to be turned into heat. Consequently, the difference in the reached temperature of the amorphous silicon film 62 between the areas A and B is not diminished, such that the favorable effect of the present invention is not achieved.

It is therefore desirable that, in this second illustrative application, the wavelength of the illuminated laser light is not less than 300 nm which is the wavelength exhibiting a predetermined value of transmittance in the glass substrate.

The present second illustrative application is not limited to the above-described structure. The laser oscillator 71 may be used not only for radiating a solid laser, such as Nd:YAG laser, or semiconductor laser, but also for radiating the excimer laser using an excimer laser light source. In this second illustrative application, the film thickness of the amorphous silicon film is controlled at the outset to be in an optimum range, with respect to the wavelength of the illuminated laser light, in order to provide for a homogeneous crystal grain size of the generated polysil icon film. Thus, the polysilicon film of a homogeneous crystal grain size may be formed, even if the light intensity is varied from one pulse to the next, as in the excimer laser, thereby reducing the rate of rejects.

The present invention is not limited to the above-described embodiments, but can be modified by the skilled artisan by correction or substitution of the embodiments within the scope as defined in the claims and not departing from the purport of the invention.

1. A laser annealing apparatus for annealing a substance formed on a major surface of a substrate, by illuminating the laser light on the surface of said substance, comprising:
laser light radiating means for radiating the laser light in a pulsed fashion at a preset period for illuminating said laser light radiated in the pulsed fashion on the surface of said substance; and
movement controlling means for moving an illuminating position of the laser light radiated from said laser light radiating means on the surface of said substance by controlling the location of said laser light radiating means and/or said substrate; wherein
with a time interval as from a timing of radiating the laser light of one pulse to the surface of said substance until a timing that the temperature of the substrate raised as a result of the illumination of one pulse of the laser light on the surface of said substance reverts to an original temperature of the substrate, as a reference period,
said laser light radiating means radiates the laser light in a pulsed fashion with a period shorter than said reference period; and wherein
said movement controlling means causes movement of the illuminating position of said laser light radiated in the pulsed fashion from said laser light radiating means on the surface of said substance so that the laser light is illuminated a plural number of times on the same position on the surface of said substance.

2. A laser annealing method for annealing a substance formed on a major surface of a substrate, by illuminating the laser light on the surface of said substance, comprising:
a time interval as from a timing of radiating the laser light of one pulse to the surface of said substance until a timing that the temperature of the substrate raised as a result of the illumination of the one pulse of the laser light on the surface of said substance reverts to an original temperature of the substrate, being a reference period,
radiating the laser light in a pulsed fashion with a period shorter than said reference period; and
controlling the illuminated position of said laser light radiated in the pulsed fashion from said laser light radiating means on the surface of said substance so that the laser light is illuminated a plural number of times on the same position on the surface of said substance.

3. A method for producing a thin film transistor having a polysilicon film, comprising:
a laser annealing step of illuminating laser light on an amorphous silicon film formed on a substrate for annealing said amorphous silicon film for transforming said amorphous silicon film into a polysilicon film;
said laser annealing step radiating pulses of said laser light to a surface of said amorphous silicon film at a period shorter than a reference period; said reference period being a time interval as from a timing of radiating the laser light of one pulse to the surface of said substance until a timing that the temperature of the substrate raised as a result of the illumination of the one pulse of the laser light on the surface of said substance reverts to an original temperature of the substrate;
said laser annealing step controlling the illuminating position of said laser light on the surface of said amorphous silicon film so that said laser light radiated in a pulsed fashion is radiated a plurality of numbers of times on the same position on the surface of said amorphous silicon film.

4. A laser annealing apparatus for annealing a substance formed on a major surface of a substrate, by illuminating the laser light on the surface of said substance, comprising:
a plurality of laser light radiating means radiating pulses of said laser light at a predetermined period;
laser light synthesizing means for synthesizing a plurality of laser light beams radiated from said plural laser light radiating means for radiating the synthesized laser light on the surface of said substance; and
timing controlling means for controlling the radiating timings of the respective laser light beams radiated from said plural laser light radiating means;
said timing controlling means equating the periods of radiation of the laser light beams of said plural laser light radiating means; said timing controlling means operating so that, before the emission of the laser light radiated from an optional laser light radiating means comes to a close, laser light is radiated from the remaining laser light radiating means by way of shifting the timing of radiation of the laser light beams of the respective laser light radiating means.

5. The laser annealing apparatus according to claim 4 wherein said plural laser light radiating means include a solid laser light source outputting pulsed laser light and radiates pulses of the laser light output from said solid laser light source.

6. The laser annealing apparatus according to claim 4 wherein said plural laser light radiating means include a continuous wave light source for continuous oscillation of the laser light and generates pulsed laser light to radiate the generated pulsed laser light by injection seeding having the laser light from said continuous wave light source as the fundamental wave.

7. A laser annealing method for annealing a substance formed on a major surface of a substrate by radiating laser light on the surface of said substance, said method comprising:
radiating pulses of a plurality of laser light beams at a predetermined period, synthesizing the radiated plural laser light beams and illuminating the synthesized laser light beams on the surface of said substance;
equating the periods of radiation of the pulses of each laser light beam, and managing control to shift the timings of radiation of the pulses of said plural laser light beams to a timing such that, before the radiation of an optional one of the laser light beams comes to a close, the remaining laser light beams are radiated.

8. The laser annealing method according to claim 7 wherein said plural laser light beams are radiated from a plurality of solid laser light sources outputting pulsed laser light beams.

9. The laser annealing method according to claim 7 wherein a pulsed laser light beam is generated by injection seeding having the laser light from a continuous wave light source as the fundamental light and wherein the pulsed laser light beam generated is radiated.

10. A method for producing a thin film transistor having a polysilicon film, comprising:
a laser annealing step of illuminating laser light on an amorphous silicon film formed on a substrate for annealing said amorphous silicon film for transforming said amorphous silicon film into a polysilicon film;
said laser annealing step radiating pulses of a plurality of laser light beams at a preset period and synthesizing the radiated plural laser light beams to illuminate the synthesized laser light beams on the surface of said substance;
said laser annealing step equating the periods of radiation of the pulses of the laser light beams and managing control for shifting the timing of radiation of pulses of said plural laser light beams so that, before the light radiation of an optional one of the laser light beams comes to a close, pulses of the remaining laser light beams are radiated.

11. The method for producing a thin film transistor according to claim 10 wherein, in said laser annealing step, said plural laser light beams are radiated from a plurality of solid laser light sources outputting pulsed laser light beams.

12. The method for producing a thin film transistor according to claim 10 wherein, in said laser annealing step, pulsed laser light beams are generated by injection seeding having the laser light from a continuous wave light source as the fundamental light.

13. A laser annealing apparatus for annealing a substance formed on a major surface of a substrate, by illuminating the laser light on the surface of said substance, comprising:
first laser light beam generating means for generating a first laser light beam in which the energy of a predetermined portion thereof is different from the energy of the remaining portion thereof and in which the energy distribution of said remaining portion is homogenized;
second laser light beam generating means for generating a second laser light beam having homogenized energy distribution;
illuminating means for synthesizing the first laser light beam and the second laser light beam to produce a synthesized laser light beam and illuminating the synthesized laser light beam to the surface of said substance; and
controlling means for controlling the radiation timing of the first laser light beam radiated from said first laser light beam generating means and the radiation timing of the second laser light beam radiated from said second laser light beam generating means;
said controlling means causing the first laser light beam generated by said first laser light beam generating means to be illuminated on the surface of said substance and subsequently causing the second laser light beam generated by said second laser light beam generating means to be illuminated on the surface of said substance.

14. The laser annealing apparatus according to claim 13 wherein said first and second laser light beam generating means radiate pulsed laser light beams.

15. The laser annealing apparatus according to claim 14 wherein said first and second laser light beam generating means each include a solid laser light source and radiate said first and second laser light beams based on the laser light beams generated by said solid laser light sources.

16. The laser annealing apparatus according to claim 14 wherein said controlling means control the output timing and the pulse period of the respective pulses of said laser light beams.

17. The laser annealing apparatus according to claim 14 wherein said first and second laser light beam generating means each include a continuous wave light source continuously oscillating the laser light beam, said first and second laser light beam generating means generating pulsed laser light beams to radiate the generated pulsed laser light beam by injection seeding having the laser light beam from said continuous wave light source as the fundamental wave.

18. The laser annealing apparatus according to claim 14 further comprising:
movement means for causing movement of the illuminating position of the laser light beam on said substance;
said controlling means controlling the output timing and the pulse period of respective pulses of the laser light beam and driving said movement means to control the illuminating positions of respective light pulses illuminated on said substance.

19. A laser annealing method for annealing a substance formed on a major surface of a substrate, by illuminating the laser light on the surface of said substance, comprising:
generating a first laser light beam in which the energy of a preset portion thereof is different from that of the remaining portion thereof and in which the energy distribution of said remaining portion is homogenized;
generating a second laser light beam having homogenized energy distribution;
synthesizing the first laser light beam and the second laser light beam to produce a synthesized laser light beam and illuminating the synthesized laser light beam to the surface of said substance; and
controlling the radiation timing of the first laser light beam and the radiation timing of the second laser light beam so that, after illuminating the first laser light beam on the surface of said substance, the second laser light beam is illuminated on the surface of said substance.

20. The laser annealing method according to claim 19 wherein said first and second laser light beams are pulsed laser light beams.

21. The laser annealing method according to claim 20 wherein said first and second laser light beams are radiated based on a laser light beam radiated from a solid laser light source.

22. The laser annealing method according to claim 20 wherein the output timing and the pulse period of each light pulse of the laser light beam are controlled.

23. The laser annealing method according to claim 20 wherein a pulsed laser light beam is generated by injection seeding having the laser light beam from said continuous wave light source as the fundamental wave and wherein the generated pulsed laser light beam is radiated as each of the first and second laser light beams.

24. The laser annealing method according to claim 20 wherein the output timing and the pulse period of respective pulses of the laser light beam and the illuminating position of the laser light beam on said substance are controlled to control the illuminating position of each pulsed laser light beam on said substance.

25. A method for manufacturing a thin-film transistor of a bottom gate structure, comprising:
a step of forming a polysilicon film by illuminating a laser light beam of a wavelength not less than 250 nm and not larger than 550 nm, radiated from a solid laser light source, to an amorphous silicon film formed on a substrate, to form the polysilicon film.

26. The method for manufacturing the thin-film transistor according to claim 25 wherein, in said polysilicon film forming step, a laser light beam of a wavelength not less than 250 nm and not larger than 550 nm, obtained on wavelength conversion of a YAG laser or a YLF laser, is illuminated.

27. The method for manufacturing the thin-film transistor according to claim 25 wherein, in said polysilicon film forming step, a laser light beam of a wavelength not less than 250 nm and not larger than 550 nm, radiated from a semiconductor laser light source, is illuminated.

28. A method for manufacturing a thin-film transistor of a bottom gate structure, comprising:
a film forming step of forming an amorphous silicon film on a substrate; and
a polysilicon film forming step of forming a polysilicon film by illuminating a laser light beam on the resulting amorphous silicon film; wherein
in said film forming step, the film thickness of said amorphous silicon film is controlled, depending on the wavelength of the laser light beam, so that the transmittance of the laser light beam is not less than 2% and not larger than 20%.

29. The method for manufacturing a thin-film transistor according to claim 28 wherein, in said polysilicon film forming step, a laser light beam radiated from a solid laser light source is illuminated.

30. The method for manufacturing a thin-film transistor according to claim 29 wherein, in said polysilicon film forming step, a laser light beam radiated from a YAG laser light source or a YLF laser light source, or harmonics obtained on wavelength conversion of said laser light beam, is illuminated.

31. The method for manufacturing a thin-film transistor according to claim 28 wherein, in said polysilicon film forming step, a laser light beam radiated from a semiconductor laser light source is illuminated.

32. The method for manufacturing a thin-film transistor according to claim 28 wherein, in said polysilicon film forming step, a laser light beam of a wavelength not less than 300 nm and not larger than 550 nm is illuminated.

33. An apparatus for manufacturing a thin-film transistor in which an amorphous silicon film formed on a substrate of a bottom gate structure is laser-annealed, comprising:
laser oscillating means for oscillating a laser light beam of a solid laser of a wavelength not less than 250 nm and not larger than 550 nm; and
laser illuminating means for illuminating the oscillated laser light beam to said amorphous silicon film.

34. The apparatus for manufacturing a thin-film transistor according to claim 33 wherein said laser oscillating means effects wavelength conversion of a YAG laser or a YLF laser to illuminate harmonics of a wavelength not less than 250 nm and not larger than 550 nm.

35. The apparatus for manufacturing a thin-film transistor according to claim 33 wherein said laser oscillating means oscillates a laser light beam of a semiconductor laser of a wavelength not less than 250 nm and not larger than 550 nm.

36. An apparatus for manufacturing a thin-film transistor of a bottom gate structure, comprising:
film forming means for forming an amorphous silicon film on a substrate;
laser oscillating means for oscillating a laser light beam; and
laser illuminating means for illuminating the oscillated laser light beam on said amorphous silicon film;
said film forming means controlling the film thickness of said amorphous silicon film, depending on the wavelength of said laser light beam, so that the transmittance of said laser light beam is not less than 2% and not larger than 20%.

37. The apparatus for manufacturing a thin-film transistor according to claim 36 wherein said laser oscillating means oscillates a laser light beam of a solid laser.

38. The apparatus for manufacturing a thin-film transistor according to claim 37 wherein said laser oscillating means oscillates a laser light beam of the YAG laser or the TLF laser;
said laser illuminating means illuminating said laser light beam or harmonics obtained on wavelength conversion of said laser light beam.

39. The apparatus for manufacturing a thin-film transistor according to claim 36 wherein said laser oscillating means oscillates a laser light beam of a semiconductor laser.

40. The apparatus for manufacturing a thin-film transistor according to claim 36 wherein said laser oscillating means oscillates a laser light beam of a wavelength not less than 300 nm and not larger than 550 nm.
